(19) United States
(12) Patent Application Publication
(10) Pub. No.: US 2008/0230820 A1
(43) Pub. Date: Sep. 25, 2008

(54) SEMICONDUCTOR DEVICE

(76) Inventors: Satoshi Maeda, Tokyo (JP); Hidehiro Harata, Tokyo (JP); Hiroyuki Kono, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/014,020

(22) Filed: Jan. 14, 2008

(30) Foreign Application Priority Data
Mar. 20, 2007 (JP) 2007-071836

(51) Int. Cl. H01L 29/94

(52) U.S. Cl. 257/296; 257/E29.345

(57) ABSTRACT

Coexistence of the realization of high-capacity of a capacitive element and the area reduction of a semiconductor device is aimed at. A plurality of capacitive elements from which a kind differs mutually are accumulated and arranged on a semiconductor substrate, and they are connected in parallel. These capacitive elements are arranged to the same plane region, and make a plane size almost the same. A lower capacitive element is an MOS type capacitive element which uses as both electrodes the n-type semiconductor region formed in the semiconductor substrate, and the upper electrode formed via the insulation film on the n-type semiconductor region. The MIM type capacitive element formed with the pattern of the comb-type of a wiring is arranged in the upper part of a lower capacitive element, and this is connected with a lower capacitive element in parallel.

### CROSS-REFERENCE TO RELATED APPLICATION

The present application claims priority from Japanese patent application No. 2007-71836 filed on Mar. 20, 2007, the content of which is hereby incorporated by reference into this application.

### FIELD OF THE INVENTION

The present invention relates to a semiconductor device, and particularly relates to an effective technology in the application to the semiconductor device which has a capacitive element.

### DESCRIPTION OF THE BACKGROUND ART

Various semiconductor devices are manufactured by forming MISFET, a capacitor, etc. on a semiconductor substrate and connecting between each element with a wiring.

The technology forming the first MIM capacitance that consists of the first metallic film, the first insulation film, and the first electrode, and the second MIM capacitance that consists of the second metallic film, the second insulation film, and the second electrode on a silicon substrate, and connecting such MIM capacitances in parallel is described in Japanese patent laid-open No. 2006-49486 (Patent Reference 1).

The technology laminating by turns the first layer by which the wiring of the first electrode extending and existing in the first direction and the wiring of the second electrode extending and existing in the first direction have been arranged by turns, and the second layer by which the wiring of the first electrode extending and existing in the second direction and the wiring of the second electrode extending and existing in the second direction have been arranged by turns, and forming a capacitor between the first electrode and the second electrode is described in Japanese patent laid-open No. 2006-128164 (Patent Reference 2).

The technology arranging a capacitive element between power supplies formation region between the input/output cells which are the generation sources of an electromagnetism noise, forming an MISFET element in the capacitive element between power supplies formation region concerned, and using the gate capacitance element which comprises the gate electrode, the gate insulation film, and the semiconductor substrate of the MISFET element concerned as the capacitive element between power supplies is described in Japanese patent laid-open No. 2006-186156 (Patent Reference 3).

In Japanese patent laid-open No. 2005-72233 (Patent Reference 4), the technology of electrically insulating with the latter capacitive element and forming the capacitive element using the line capacity of the conductor line right above the capacitive element which comprises the polysilicon layer of two layers, and the insulation film inserted between them is described.

[Patent Reference 1] Japanese patent laid-open No. 2006-49486

[Patent Reference 2] Japanese patent laid-open No. 2006-128164

[Patent Reference 3] Japanese patent laid-open No. 2006-186156

[Patent Reference 4] Japanese patent laid-open No. 2005-72233

### SUMMARY OF THE INVENTION

According to the analyses of the present inventor, the following thing was understood.

In recent years, area reduction (reduction of a plane size) of a semiconductor device has been required. In order to aim at area reduction of the semiconductor device, it is effective to make small the size of each element formed on the semiconductor substrate.

On the other hand, although a capacitive element can be formed with the electrode which faces on both sides of an insulation film (dielectric film), a capacitance value is proportional to an electrode area. For this reason, when aiming at realization of high-capacity of a capacitive element, it is common to enlarge area of the capacitive element. However, since this enlarges area of the capacitive element formation region, it will enlarge area of a semiconductor device. For this reason, to form the capacitive element of a big capacitance value in a small plane region, and to aim at coexistence of the realization of high-capacity of the capacitive element and the area reduction of a semiconductor device are desired.

A purpose of the present invention is to offer the technology which can carry out area reduction of the semiconductor device which has a capacitive element.

Other purpose of the present invention is to offer the technology in which coexistence of the realization of high-capacity of a capacitive element and the area reduction of a semiconductor device can be aimed at.

The above-described and the other purposes and novel features of the present invention will become apparent from the description herein and accompanying drawings.

Of the inventions disclosed in the present application, typical ones will next be summarized briefly.

The present invention accumulates a plurality of capacitive elements from which a kind differs mutually on a semiconductor substrate, arranges them, and connects them in parallel.

The present invention accumulates a plurality of capacitive elements from which characteristics differ mutually on a semiconductor substrate, arranges them, and connects them in parallel.

Advantages achieved by some of the most typical aspects of the invention disclosed in the present application will be briefly described below.

Area reduction of the semiconductor device which has a capacitive element can be done.

Coexistence of the realization of high-capacity of a capacitive element and the area reduction of a semiconductor device can be aimed at.

### BRIEF DESCRIPTION OF THE DRAWINGS

FIG. 1 is a principal part circuit diagram of the semiconductor device of Embodiment 1 of the present invention;

FIGS. 2 to 4 are principal part cross-sectional views of the semiconductor device of Embodiment 1 of the present invention;

FIGS. 5 to 10 are principal part plan views of the semiconductor device of Embodiment 1 of the present invention;

FIG. 11 is a graph which shows an example of MOS type capacitive element single C-V characteristics;

FIG. 12 is a graph which shows an example of MIM type capacitive element single C-V characteristics which used the comb-type wiring pattern;

FIG. 13 is a graph which shows an example of the C-V characteristics of the circuit of structure of having done parallel connection of an MOS type capacitive element, and the MIM type capacitive element using a comb-type wiring pattern;

FIG. 14 is a table showing the voltage coefficient of the C-V characteristics of FIG. 11-FIG. 13;

FIG. 15 is a principal part cross-sectional view of the semiconductor device of Embodiment 2 of the present invention;

FIG. 16 is a principal part plan view of the semiconductor device of Embodiment 2 of the present invention;

FIG. 17 is a principal part circuit diagram of the semiconductor device of Embodiment 3 of the present invention;

FIGS. 18 and 19 are principal part cross-sectional views of the semiconductor device of Embodiment 3 of the present invention;

FIGS. 20 and 21 are principal part plan views of the semiconductor device of Embodiment 3 of the present invention;

FIG. 22 is a principal part cross-sectional view of the semiconductor device of Embodiment 3 of the present invention;

FIG. 23 is a principal part circuit diagram of the semiconductor device of Embodiment 4 of the present invention;

FIGS. 24 and 25 are principal part cross-sectional views of the semiconductor device of Embodiment 4 of the present invention;

FIG. 26 is a principal part circuit diagram of the semiconductor device of Embodiment 5 of the present invention;

FIGS. 27 and 28 are principal part cross-sectional views of the semiconductor device of Embodiment 5 of the present invention;

FIG. 29 is a principal part plan view of the semiconductor device of Embodiment 5 of the present invention;

FIG. 30 is a principal part circuit diagram of the semiconductor device of Embodiment 6 of the present invention;

FIGS. 31 and 32 are principal part cross-sectional views of the semiconductor device of Embodiment 6 of the present invention; and

FIGS. 33 to 36 are plan views of a capacitor formation region.

### DETAILED DESCRIPTION OF THE PREFERRED EMBODIMENTS

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated. And, in the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number. Further, in the below-described embodiments, it is needless to say that the constituting elements (including element steps) are not always essential unless otherwise specifically indicated or principally apparent that they are essential. Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

Hereafter, embodiments of the invention are explained in detail based on drawings. In all the drawings for describing the embodiments, members of a like function will be identified by like reference numerals and overlapping descriptions will be omitted. And, in the following embodiments, except the time when especially required, explanation of identical or similar part is not repeated in principle.

In the drawing used by an embodiment, even if it is a cross-sectional view, in order to make a drawing legible, hatching may be omitted. Hatching may be attached in order to make a drawing legible, even if it is a plan view.

### Embodiment 1

The semiconductor device of this embodiment is explained with reference to drawings. The semiconductor device of this embodiment is a semiconductor device which has a capacitive element.

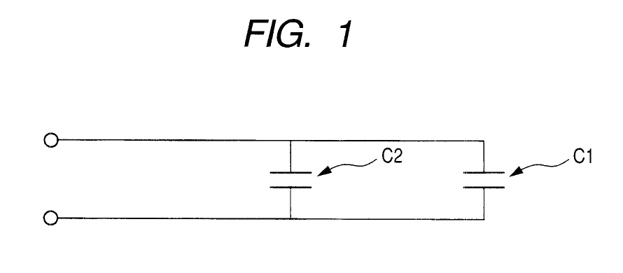

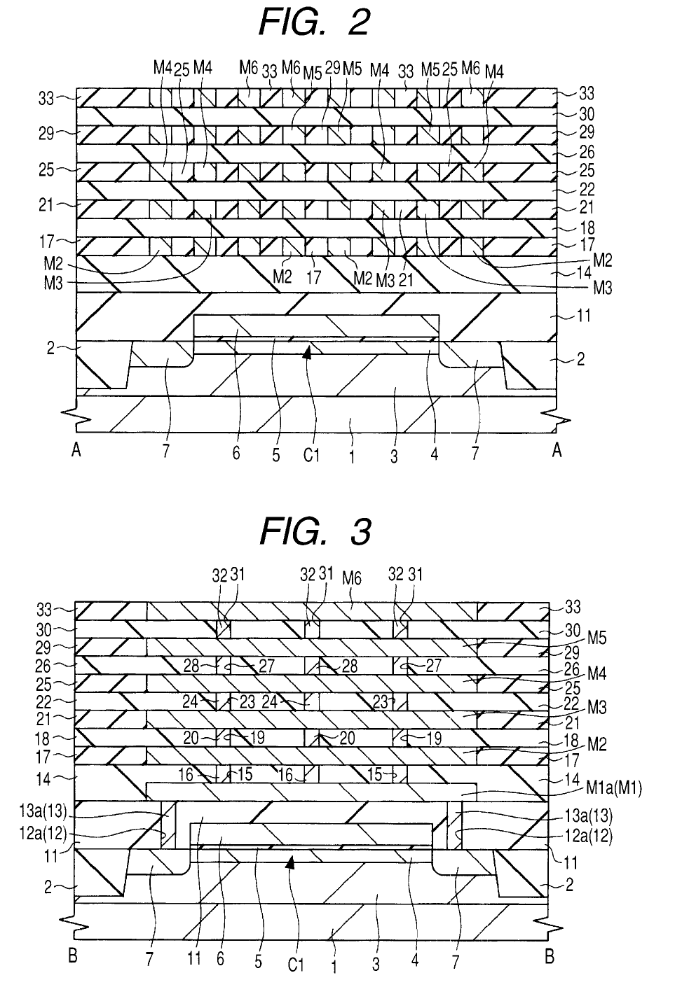

FIG. 1 is a principal part circuit diagram of the semiconductor device of this embodiment, FIG. 2-FIG. 4 are the principal part cross-sectional views of the semiconductor device of this embodiment, and FIG. 5-FIG. 10 are the principal part plan views of the semiconductor device of this embodiment.

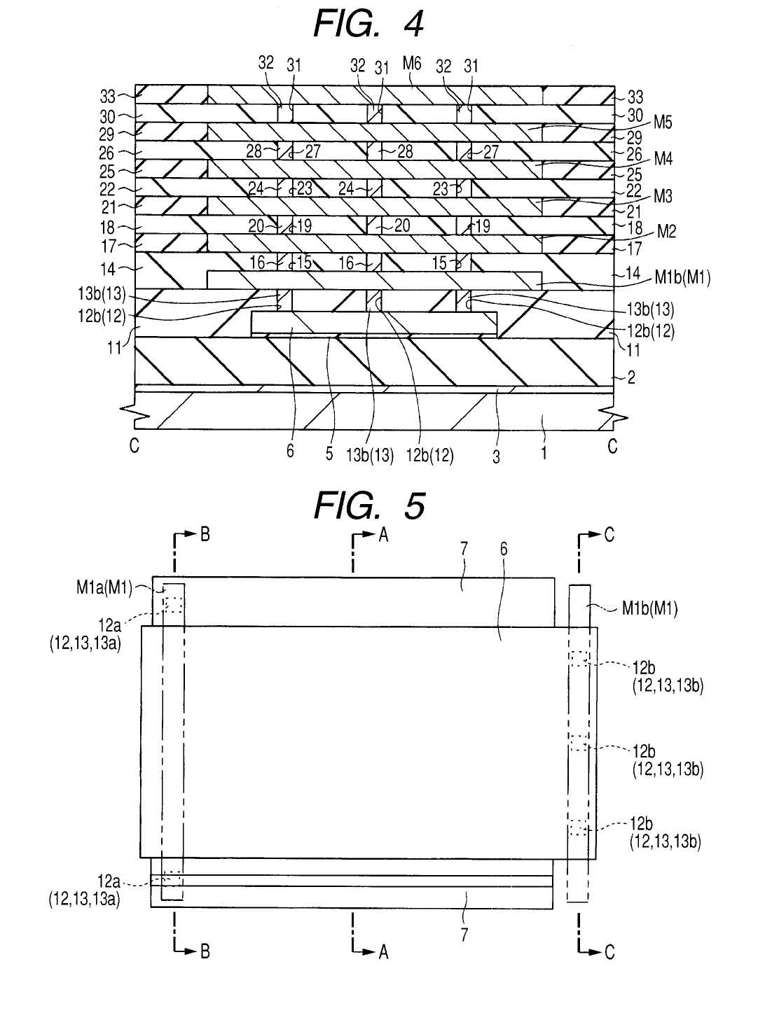

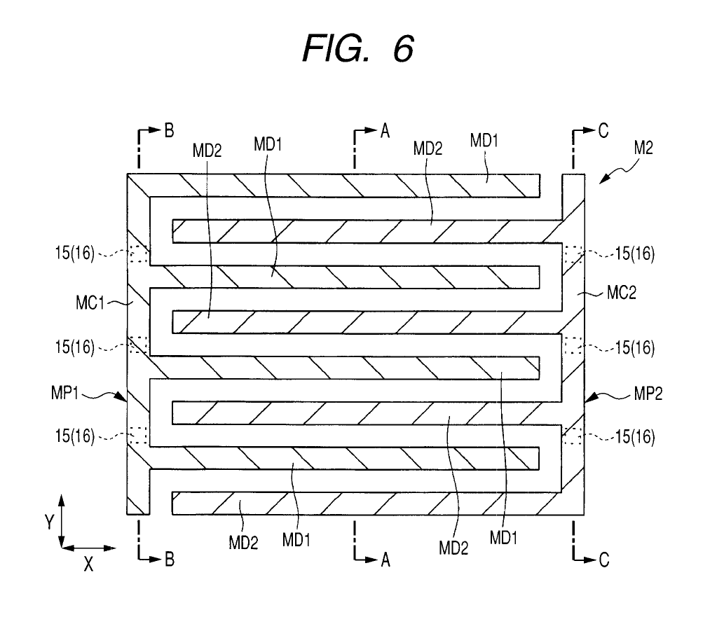

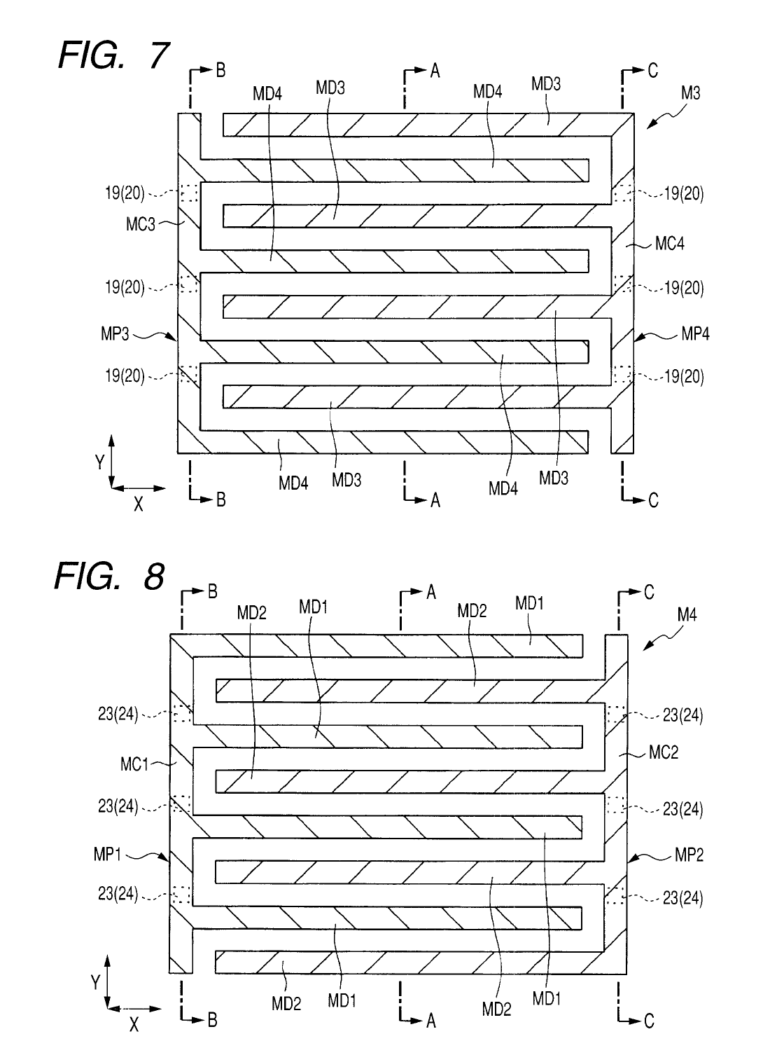

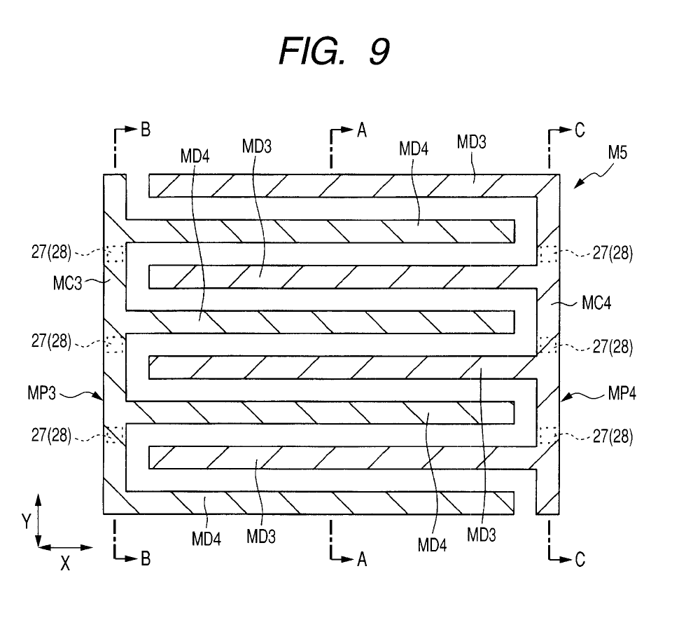

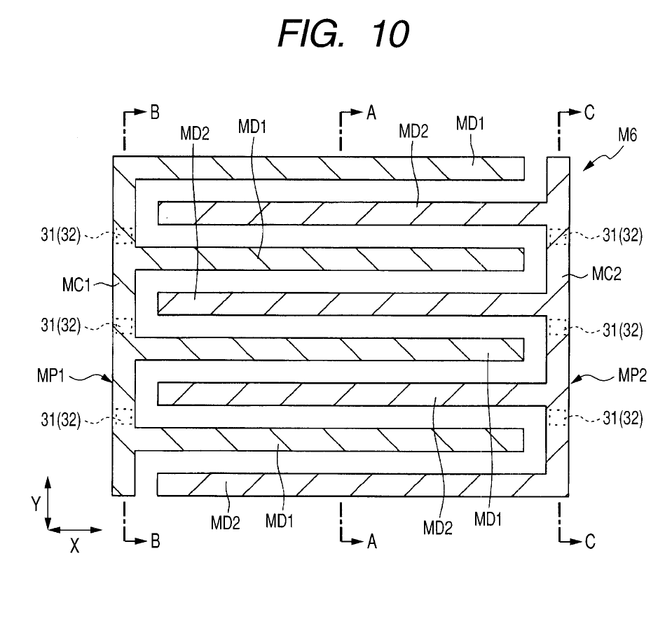

The circuit (equivalent circuit) formed in the capacitor formation region of the semiconductor device shown in FIG. 2-FIG. 10 is shown in FIG. 1. In FIG. 2-FIG. 4, the cross-sectional view of the capacitor formation region of a semiconductor device is shown, and, as for the upper structure than insulation film 33 and wiring M6, illustration is omitted. A different layer of the same plane region (here a capacitor formation region) of a semiconductor device is shown in FIG. 5-FIG. 10. The plane layout of upper electrode 6, n-type semiconductor region 7, contact hole 12 (12a, 12b), and wiring M1 is shown in FIG. 5. At FIG. 6, the plane layout of wiring M2 which is the second layer wiring is shown, in FIG. 7, the plane layout of wiring M3 which is the third layer wiring is shown, and the plane layout of wiring M4 which is the fourth layer wiring is shown in FIG. 8. In FIG. 9, the plane layout of wiring M5 which is the fifth layer wiring is shown, and the plane layout of wiring M6 which is the sixth layer wiring is shown in FIG. 10. Although each of FIG. 6-FIG. 10 is a plan view, in order to make a drawing legible, hatching is given to wiring M2, M3, M4, M5, and M6. The section of the A-A line of FIG. 5-FIG. 10 corresponds to FIG. 2, the section of the B-B line of FIG. 5-FIG. 10 corresponds to FIG. 3, and the section of the C-C line of FIG. 5-FIG. 10 corresponds to FIG. 4.

As shown also in the circuit diagram of FIG. 1, the semiconductor device of this embodiment is connecting capacitive element C1 and capacitive element C2 of a different kind in parallel, and forms the large capacity capacitive element as total. And this plurality of capacitive elements C1 and C2 from which a kind differs mutually are accumulated on a different layer of the same plane region (the capacitor formation region shown in FIG. 2-FIG. 10 here) on semiconductor substrate 1, they are arranged, and they are connected in parallel.

The concrete structure of the semiconductor device of this embodiment is explained with reference to FIG. 2-FIG. 10.

As shown in FIG. 2-FIG. 4, semiconductor substrate 1 which forms the semiconductor device of this embodiment consists of p type single crystal silicon which has the resistivity of about 1˜10 Ωcm, for example. Semiconductor substrate 1 which forms the semiconductor device of this embodiment has the capacitor formation region in which capacitive elements C1 and C2 are formed, and the cross-sectional view or plan view of this capacitor formation region is shown in FIG. 2-FIG. 10.

As shown in FIG. 2-FIG. 4, element isolation region 2 is formed in the main surface of semiconductor substrate 1. Element isolation region 2 consists of an insulator (for example, silicon oxide) embedded in the element isolation trench, and can be formed, for example, by the STI (Shallow Trench Isolation) method or the LOCOS (Local Oxidization of Silicon) method.

Well region (p type well region) 3 is formed in the main surface of semiconductor substrate 1 comprising a capacitor formation region. Well region 3 can be formed by for example, doing the ion implantation of the impurity (p type impurity) to semiconductor substrate 1 etc.

Capacitive element C1 is formed in the main surface of semiconductor substrate 1 in the capacitor formation region. Capacitive element C1 is formed with n-type semiconductor region (impurity diffused layer) 4 formed in the layer part of well region 3 in a capacitor formation region, insulation film 5 formed on n-type semiconductor region 4, upper electrode (an upper electrode film, a conductor film, a conductor film pattern) 6 formed on insulation film 5, and n-type semiconductor region (impurity diffused layer) 7 formed in well region 3 of the both sides of upper electrode 6, and is the so-called MOS type capacitive element.

An MOS type capacitive element uses the channel region, gate insulation film, and gate electrode of MISFET as the lower electrode, capacitance insulation film, and upper electrode of an MOS type capacitive element, respectively. A high concentration impurity diffused layer (here n-type semiconductor region 4) is formed in the portion corresponding to a channel region, and let this be a lower electrode. Also when calling it an MOS type capacitive element, a capacitance insulation film (here insulation film 5) is not limited to an oxide film, but can also use insulation films other than an oxide film for a capacitance insulation film (here insulation film 5). Therefore, an MOS type capacitive element can be regarded as the capacitive element which uses a part of semiconductor substrate 1 (n-type semiconductor region 4 which introduced the impurity into semiconductor substrate 1 here, and was formed) as a lower electrode, and use as an upper electrode the conductor layer (here upper electrode 6) formed via the insulation film (here insulation film 5) on semiconductor substrate 1 (on n-type semiconductor region 4).

N-type semiconductor region 4 can be formed by doing the ion implantation of the impurity of n types, such as phosphorus (P) or arsenic (As), to semiconductor substrate 1 before insulation film 5 formation etc., for example.

Insulating film 5 is formed in the main surface of semiconductor substrate 1 (on namely, upper surface of n-type semiconductor region 4), for example, consists of a thin silicon oxide film etc., and can be formed by a thermal oxidation method etc. This insulation film 5 is formed together (simultaneously) at the time of forming the gate insulation film for MISFET, and consists of an insulation film of the same layer as a gate insulation film of MISFET (formed in the region outside the capacitor formation region).

Upper electrode 6 is formed on insulation film 5 of the capacitor formation region, consists of a patterned conductor film (conductor layer), and consists of a silicon film (more preferably, silicon film to which the impurity was introduced and which was made into low specific resistance) preferably. Therefore, n-type semiconductor region 4 and upper electrode 6 have faced via insulation film 5 in between. Upper electrode 6 can be formed by forming the conductor film which consists of a polycrystalline silicon film (doped polysilicon film) etc. on the whole surface of semiconductor substrate 1 after formation of insulation film 5, and patterning this conductor film using the photolithography method and the dry etching method. When patterning the conductor film for upper electrode 6, the gate electrode which consists of a patterned conductor film can be formed in an MISFET formation schedule region. Therefore, upper electrode 6 of the capacitor formation region is formed together (simultaneously) at the time of forming the gate electrode of MISFET, and consists of a conductor film of the same layer as the gate electrode of MISFET.

N-type semiconductor region 7 is formed by self align to upper electrode 6 in well region 3, and adjoins n-type semiconductor region 4. N-type semiconductor region 7 can be formed by doing the ion implantation of the impurity of n types, such as phosphorus (P), to the region (well region 3) of the both sides of upper electrode 6 etc. When forming n-type semiconductor region 7, ion implantation can be done also to the region of the both sides of the gate electrode of the MISFET formation schedule region which is not illustrated, and the semiconductor region for source/drains (not shown) can be formed. Therefore, n-type semiconductor region 7 of the capacitor formation region is formed together (simultaneously) at the time of forming the semiconductor region for the source/drain regions of MISFET, and consists of a semiconductor region of the same layer as the semiconductor region for the source/drains (impurity diffused layer) of MISFET. The plane layout of upper electrode 6 and n-type semiconductor region 7 is shown in FIG. 5, and n-type semiconductor region 7 is formed in the both sides of upper electrode 6. In FIG. 5, n-type semiconductor region 4 is formed under upper electrode 6 and between n-type semiconductor regions 7, although it hides in upper electrode 6 and is not illustrated.

Therefore, in a capacitor formation region, capacitive element C1 is formed of these n-type semiconductor regions 4, insulation films 5, upper electrodes 6, and n-type semiconductor regions 7, and capacitive element C1 can be formed with the almost same steps as MISFET.

N-type semiconductor region 4 functions as one electrode (lower electrode) of capacitive element C1, upper electrode 6 functions as the other electrode (upper electrode) of capacitive element C1, and insulation film 5 functions as a capacitance insulation film (dielectric film) of capacitive element C1. When n-type semiconductor region 4 is MISFET, it will act as a channel region, but in order to make it function as a lower electrode of capacitive element C1, the n type impurity is introduced into n-type semiconductor region 4 at high concentration rather than the channel region of usual MISFET. N-type semiconductor region 7 functions as a lead-out part (contact part) of the lower electrode (here n-type semiconductor region 4) of capacitive element C1.

Although illustration is not done, a side wall insulation film can also be formed on the side wall of upper electrode 6. Although illustration is not done, a metal silicide layer can also be formed in the upper part of upper electrode 6 and n-type semiconductor region 7 according to a salicide process etc. When forming the metal silicide layer, the contact resistance between upper electrode 6 and n-type semiconductor region 7, and plug 13 etc. can be reduced.

On semiconductor substrate 1, insulation film (interlayer insulation film) 11 is formed so that upper electrode 6 may be covered. Insulating film 11 is formed with the laminated film of a silicon nitride film and a silicon oxide film, or the single body film of the silicon oxide film.

Contact hole (an opening, a hole, a through hole) 12 is formed in insulation film 11. In contact hole 12, plug (a conductor part, the conductor part for connection) 13 which consists of an electric conduction film which makes a tungsten (W) film a main body is formed and embedded.

In the capacitor formation region, contact hole 12, and plug 13 which fills it are formed in the upper part of n-type semiconductor region 7, and the upper part of upper electrode 6.

Contact hole 12a of the contact holes 12 is formed in the upper part of n-type semiconductor region 7, and n-type semiconductor region 7 is exposed at the bottom. Contact hole 12b of the contact holes 12 is formed in the upper part of upper electrode 6, and upper electrode 6 is exposed at the bottom. Therefore, as for plug 13a embedded in contact hole 12a among plugs 13, the bottom is electrically connected in contact with n-type semiconductor region 7. As for plug 13b embedded in contact hole 12b among plugs 13, the bottom is electrically connected in contact with upper electrode 6.

On insulation film 11 where plug 13 was embedded, wiring M1 is formed as the first layer wiring (an undermost layer wiring, a wiring layer). Wiring M1 can be formed by for example, forming conductor films, such as a tungsten film, on insulation film 11 where plug 13 was embedded, and patterning this conductor film using the photolithography method and the dry etching method etc. Wiring M1 has a pattern as shown in FIG. 5 in the capacitor formation region. Wiring M1 is formed mainly with metal (a metallic material, material in which metallic electrical conduction is shown) like tungsten.

Insulating film (interlayer insulation film) 14 is formed so that wiring M1 may be covered on insulation film 11. Through hole (an opening, a hole) 15 is formed in insulation film 14, and plug (conductor part) 16 is formed and embedded in through hole 15. Plug 16 is electrically connected in contact with wiring M1 at the bottom.

On insulation film 14 where plug 16 is embedded, insulation film (interlayer insulation film) 17 is formed. A wiring groove, and wiring M2 embedded in this wiring groove are formed in this insulation film 17. Wiring M2 can be formed using damascene technology (here single damascene technology), and can use a copper wiring which uses copper as a principal component. Wiring M2 is the second layer wiring (wiring layer) of one upper layer from wiring M1. Wiring M2 has a pattern as shown in FIG. 6 in the capacitor formation region.

On insulation film 17 where wiring M2 was embedded, insulation film (interlayer insulation film) 18 is formed. Through hole (an opening, a hole) 19 is formed in insulation film 18, and plug (a conductor part, the conductor part for connection) 20 is formed and embedded in through hole 19. Plug 20 is electrically connected in contact with wiring M2 at the bottom.

On insulation film 18 where plug 20 was embedded, insulation film (interlayer insulation film) 21 is formed. A wiring groove, and wiring M3 embedded in this wiring groove are formed in this insulation film 21. Wiring M3 is the third layer wiring (wiring layer) of one upper layer from wiring M2. Wiring M3 has a pattern as shown in FIG. 7 in the capacitor formation region. Wiring M3 can be formed using damascene technology (here single damascene technology), and can use a copper wiring which uses copper as a principal component. Wiring M3 can also be formed using dual damascene (Dual-Damascene) technology, and wiring M3 and plug 20 are formed in one in this case.

The same insulation film 22, through hole 23, plug 24, insulation film 25, and wiring M4 as insulation film 18, through hole 19, plug 20, insulation film 21, and wiring M3 are similarly formed on insulation film 21 where wiring M3 was embedded. Further, the same insulation film 26, through hole 27, plug 28, insulation film 29, and wiring M5 as insulation film 18, through hole 19, plug 20, insulation film 21, and wiring M3 are similarly formed on insulation film 25 where wiring M4 was embedded. Further, the same insulation film 30, through hole 31, plug 32, insulation film 33, and wiring M6 as insulation film 18, through hole 19, plug 20, insulation film 21, and wiring M3 are similarly formed on insulation film 29 where wiring M5 was embedded.

Wiring M4 is the fourth layer wiring (wiring layer) of one upper layer from wiring M3, wiring M5 is the fifth layer wiring (wiring layer) of one upper layer from wiring M4, and wiring M6 is the sixth layer wiring (wiring layer) of one upper layer from wiring M5. Wiring M4, wiring M5, and wiring M6 have a pattern as shown in FIG. 8, FIG. 9, and FIG. 10, respectively in the capacitor formation region. Wiring M4, M5, and M6 can be formed using damascene technology (here single damascene technology), and are embedded in the wiring groove formed in insulation films 25, 29, and 33, respectively. Wiring M4, M5, and M6 can also be formed using dual damascene technology, and in this case, wiring M4 and plug 24 are formed in one, wiring M5 and plug 28 are formed in one, and wiring M6 and plug 32 are formed in one. With wirings M2-M6, a single damascene and a dual damascene may be used properly. Wirings M2-M6 are formed mainly with metal (a metallic material, material in which metallic electrical conduction is shown) like copper. When wirings M2-M6 are embedded wirings formed by the damascene method like this embodiment, they are more preferred. However, wirings M2-M6 can also be set as the wiring (for example, aluminum wiring) formed by patterning of the conductor film (metallic film) as other forms.

Although the insulation film, wiring layer and bonding pad which are the upper layer further, the protective film of the top layer, etc. are formed according to need on insulation film 33 where wiring M6 was embedded, the illustration and explanation are omitted here.

As FIG. 6-FIG. 10 show, the plane layout (plane pattern form) of wiring M2, wiring M4, and wiring M6 in a capacitor formation region is mutually the same. And the plane layout (plane pattern form) of wiring M3 and wiring 5 in a capacitor formation region is mutually the same. That is, in the capacitor formation region, the wiring (wiring M2, M4, M6, and wiring M3, M5) of two kinds of layouts is piled up by turns, and the second layer wiring-the sixth layer wiring are formed.

As shown in FIG. 6, FIG. 8, and FIG. 10, wiring M2, M4, and M6 are provided with a plurality of wiring part (electrode part, conductor part) MD1 and MD2 extending and existing to the X direction, wiring part (connection part, conductor part) MC1 which extends and exists to the Y direction and connects the end portion of wiring part MD1, and wiring part (connection part, conductor part) MC2 which extends and exists to the Y direction and connects the end portion of wiring part MD2 in the capacitor formation region. Between wiring part MC1 and wiring part MC2 which extend and exist to the Y direction, wiring part MD1 and wiring part MD2 which extend and exist to the X direction are located in a line to the Y direction by turns at the predetermined gap (preferably regular intervals). The X direction and the Y direction are directions to cross mutually, and directions to intersect perpendicularly preferably. It is preferred that the wiring width (the width or the size of the Y direction) of wiring part MD1 and MD2 are mutually the same.

As for each wiring part MD1, one end portion side (in FIG. 6, FIG. 8, and FIG. 10, left side end part) is connected to wiring part MC1, and the other-end part side (in FIG. 6, FIG. 8, and FIG. 10, right side end part) is spaced out from wiring part MC2. As for each wiring part MD2, one end portion side (in FIG. 6, FIG. 8, and FIG. 10, left side end part) is spaced out from wiring part MC1, and the other-end part side (in FIG. 6, FIG. 8, and FIG. 10, right side end part) is connected to wiring part MC2.

Therefore, in each wiring M2, M4, and M6, a plurality of wiring parts MD1 and wiring part MC1 which connects them are formed in one, and they form comb-type-shaped metallic pattern (conductor pattern, wiring pattern, metal pattern) MP1. And a plurality of wiring parts MD2 and wiring part MC2 which connects them are formed in one, and they form comb-type-shaped metallic pattern (conductor pattern, wiring pattern, metal pattern) MP2. In each wiring M2, M4, and M6, metallic pattern MP1 which consists of wiring part MD1 and MC1 and metallic pattern MP2 which consists of wiring part MD2 and MC2 are facing each other with the insulation film (in wiring M2, it corresponds to insulation film 17, in wiring M4, corresponds to insulation film 25, and, in wiring M6, corresponds to insulation film 33) intervened in between.

Since the plane layout of wiring M2, wiring M4, and wiring M6 in a capacitor formation region is the same, wiring parts MD1 of wiring M2, wiring M4, and wiring M6, wiring parts MD2 of wiring M2, wiring M4, and wiring M6, wiring parts MC1 of wiring M2, wiring M4, and wiring M6 and wiring parts MC2 of wiring M2, wiring M4, and wiring M6 are arranged (desirably with the same plane size) in the position which overlaps in plan view (preferably at the same position), respectively. That is, although the formed layer differs among metallic pattern MP1 which consists of wiring M2, and metallic pattern MP1 which consists of wiring M4 and metallic pattern MP1 which consists of wiring M6, they are arranged in the position which overlaps in plan view (preferably at the same position). Although the formed layer differs among metallic pattern MP2 which consists of wiring M2, and metallic pattern MP2 which consists of wiring M4 and metallic pattern MP2 which consists of wiring M6, they are arranged (desirably with the same plane size) in the position which overlaps in plan view (preferably at the same position). “To overlap in plan view” means that they overlap when the main surface of semiconductor substrate 1 is seen from a direction vertical to the main surface of semiconductor substrate 1.

As shown in FIG. 7 and FIG. 9, wirings M3 and M5 are provided with a plurality of wiring parts (electrode part, conductor part) MD3 and MD4 extending and existing to the X direction, wiring part (connection part, conductor part) MC3 which extends and exists to the Y direction and connects the end portion of wiring part MD4, and wiring part (connection part, conductor part) MC4 which extends and exists to the Y direction and connects the end portion of wiring part MD3 in the capacitor formation region. Between wiring part MC3 and wiring part MC4 which extend and exist to the Y direction, wiring part MD3 and wiring part MD4 which extend and exist to the X direction are located in a line to the Y direction by turns at the predetermined gap (preferably regular intervals). It is preferred that the wiring width of wiring part MD3 and MD4 are mutually the same. It is more preferred that the wiring width (the width or the size of the Y direction) of wiring parts MD1-MD4 is mutually the same. Hereby, the capacitance value of capacitive element C2 can be enlarged efficiently.

As for each wiring part MD3, one end portion side (in FIG. 7 and FIG. 9, left side end part) is spaced out from wiring part MC3, and the other-end part side (in FIG. 7 and FIG. 9, right side end part) is connected to wiring part MC4. As for each wiring part MD4, one end portion side (in FIG. 7 and FIG. 9, left side end part) is connected to wiring part MC3, and the other-end part side (in FIG. 7 and FIG. 9, right side end part) is spaced out from wiring part MC4.

Therefore, in each wiring M3 and M5, a plurality of wiring parts MD3 and wiring part MC4 which connects them are formed in one, and they form comb-type-shaped metallic pattern (conductor pattern, wiring pattern, metal pattern) MP4. And a plurality of wiring parts MD4 and wiring part MC3 which connects them are formed in one, and they form comb-type-shaped metallic pattern (conductor pattern, wiring pattern, metal pattern) MP3. And in each wiring M3 and M5, metallic pattern MP4 which consists of wiring part MD3 and MC4, and metallic pattern MP3 which consist of wiring part MD4 and MC3 are facing each other with the insulation film (insulation film 21 in the case of wiring M3, insulation film 29 in the case of wiring M5) intervened in between.

Since the plane layout of wiring M3 and wiring M5 in a capacitor formation region is the same, wiring parts MD3 of wiring M3 and wiring M5, wiring parts MD4 of wiring M3 and wiring M5, wiring parts MC3 of wiring M3 and wiring M5 and wiring parts MC4 of wiring M3 and wiring M5 are arranged (desirably with the same plane size) in the position which overlaps in plan view (preferably at the same position), respectively. That is, although the formed layer differs between metallic pattern MP3 which consists of wiring M3, and metallic pattern MP3 which consist of wiring M5, they are arranged in the position which overlaps in plan view (preferably at the same position). Although the formed layer differs between metallic pattern MP4 which consists of wiring M3, and metallic pattern MP4 which consist of wiring M5, they are arranged in the position which overlaps in plan view (preferably at the same position).

And wiring part MD3 of metallic pattern MP4 of wiring M3 and M5 and wiring part MD1 of metallic pattern MP1 of wiring M2, M4, and M6 are formed (desirably with the same plane size) in the position which overlaps in plan view (preferably at the same position). And wiring part MD4 of metallic pattern MP3 of wiring M3 and M5 and wiring part MD2 of metallic pattern MP2 of wiring M2, M4, and M6 are formed (desirably with the same plane size) in the position which overlaps in plan view (preferably at the same position). Wiring part MC3 of metallic pattern MP3 of wiring M3 and M5 and wiring part MC1 of metallic pattern MP1 of wiring M2, M4, and M6 are formed (desirable with the same plane size) in the position which overlaps in plan view (preferably at the same position). And wiring part MC4 of metallic pattern MP4 of wiring M3 and M5 and wiring part MC2 of metallic pattern MP2 of wiring M2, M4, and M6 are formed (desirable with the same plane size) in the position which overlaps in plan view (preferably at the same position).

However, wiring part MD1 of wiring M2, M4, and M6 is connected with wiring part MC1, and is not connected with wiring part MC2. On the other hand, wiring part MD3 of wiring M3 and M5 arranged in the same (overlapping) position as wiring part MD1 in plan view is connected to wiring part MC4 instead of wiring part MC3 of the same plane position as wiring part MC1, and is not connected with wiring part MC3. Wiring part MD2 of wiring M2, M4, and M6 is connected to wiring part MC2, and not connected with wiring part MC1. On the other hand, wiring part MD4 of wiring M3 and M5 arranged in the same (overlapping) position as wiring part MD2 in plan view is connected to wiring part MC3 instead of wiring part MC4 of the same plane position as wiring part MC2, and is not connected with wiring part MC4.

Through holes 19, 23, 27, and 31 and plugs 20, 24, 28, and 32 which fill them are arranged in the position which overlaps with wiring part MC1 and MC3 of wirings M2-M6 as FIG. 3, and FIG. 6-FIG. 10 also show. Wiring parts MC1 and MC3 of wirings M2-M6 are electrically connected via them. That is, wiring part MC1 of wiring M2 and wiring part MC3 of wiring M3 are electrically connected via plug 20 which fills the inside of through hole 19 between both. Wiring part MC3 of wiring M3 and wiring part MC1 of wiring M4 are electrically connected via plug 24 which fills the inside of through hole 23 between both. And wiring part MC1 of wiring M4 and wiring part MC3 of wiring M5 are electrically connected via plug 28 which fills the inside of through hole 27 between both. Wiring part MC3 of wiring M5 and wiring part MC1 of wiring M6 are electrically connected via plug 32 which fills the inside of through hole 31 between both.

Through holes 19, 23, 27, and 31 and plugs 20, 24, 28, and 32 which fill them are arranged in the position which overlaps with wiring part MC2 and MC4 of wirings M2-M6 as FIG. 4, and FIG. 6-FIG. 10 also show. Wiring part MC2 and MC4 of wirings M2-M6 are electrically connected via them. That is, wiring part MC2 of wiring M2 and wiring part MC4 of wiring M3 are electrically connected via plug 20 which fills the inside of through hole 19 between both. Wiring part MC4 of wiring M3 and wiring part MC2 of wiring M4 are electrically connected via plug 24 which fills the inside of through hole 23 between both. And wiring part MC2 of wiring M4 and wiring part MC4 of wiring M5 are electrically connected via plug 28 which fills the inside of through hole 27 between both. Wiring part MC4 of wiring M5 and wiring part MC2 of wiring M6 are electrically connected via plug 32 which fills the inside of through hole 31 between both.

Therefore, metallic pattern MP1 which consists of wiring part MD1 and MC1 of wiring M2, metallic pattern MP3 which consists of wiring part MD4 and MC3 of wiring M3, metallic pattern MP1 which consists of wiring part MD1 and MC1 of wiring M4, metallic pattern MP3 which consists of wiring part MD4 and MC3 of wiring M5, and metallic pattern MP1 which consist of wiring part MD1 and MC1 of wiring M6 are electrically connected and become the first electrode (one electrode) of capacitive element C2. Metallic pattern MP2 which consists of wiring part MD2 and MC2 of wiring M2, metallic pattern MP4 which consists of wiring part MD3 and MC4 of wiring M3, metallic pattern MP2 which consists of wiring part MD2 and MC2 of wiring M4, metallic pattern MP4 which consists of wiring part MD3 and MC4 of wiring M5, and metallic pattern MP2 which consist of wiring part MD2 and MC2 of wiring M6 are electrically connected and become the second electrode (the other electrode) of capacitive element C2. And the insulation film between the first electrode and the second electrode turns into a capacitance insulation film (dielectric film) of capacitive element C2. MIM (Metal Insulator Metal) type capacitive element C2 is formed of metallic patterns MP1-MP4 of these wirings M2-M6 (the first electrode and the second electrode), and the insulation film between metallic patterns MP1-MP4.

The total capacity of capacitive element C2 is total of the following first-13th capacitance. Namely, the first capacitance formed between metallic pattern MP1 and metallic pattern MP2 of wiring M2. The second capacitance formed between metallic pattern MP3 and metallic pattern MP4 of wiring M3. The third capacitance formed between metallic pattern MP1 and metallic pattern MP2 of wiring M4. The fourth capacitance formed between metallic pattern MP3 and metallic pattern MP4 of wiring M5. The fifth capacitance formed between metallic pattern MP1 and metallic pattern MP2 of wiring M6. The sixth capacitance formed between metallic pattern MP1 of wiring M2, and metallic pattern MP4 of wiring M3. The seventh capacitance formed between metallic pattern MP2 of wiring M2, and metallic pattern MP3 of wiring M3. The eighth capacitance formed between metallic pattern MP3 of wiring M3, and metallic pattern MP2 of wiring M4. The ninth capacitance formed between metallic pattern MP4 of wiring M3, and metallic pattern MP1 of wiring M4. The 10th capacitance formed between metallic pattern MP1 of wiring M4, and metallic pattern MP4 of wiring M5. The 11th capacitance formed between metallic pattern MP2 of wiring M4, and metallic pattern MP3 of wiring M5. The 12th capacitance formed between metallic pattern MP3 of wiring M5, and metallic pattern MP2 of wiring M6. The 13th capacitance formed between metallic pattern MP4 of wiring M5, and metallic pattern MP1 of wiring M6. Since the total capacity of capacitive element C2 can be set as total of the first-13th capacitance of the above, realization of high-capacity of the capacitive element C2 can be done.

The first-fifth capacitance is the capacitance between the metallic patterns of the same layer (here between metallic pattern MP1 and MP2 and between metallic pattern MP3 and MP4) among the first-13th capacitance of the above which forms the total capacity of capacitive element C2. Therefore, it can be considered that capacitive element C2 is a capacitive element using the capacitance between the metallic patterns of the same layer (here between metallic pattern MP1 and MP2 and between metallic pattern MP3 and MP4). It can also be considered that capacitive element C2 is a capacitive element using the fringe capacitance of the wiring pattern (here metallic patterns MP1-MP4 of M2-M6). On the other hand, capacitive element C3 explained by Embodiment 3 mentioned later is a capacitive element which did not use the capacitance between the metallic patterns of the same layer, but used only the capacitance between the metal electrodes of two layers of upper and lower sides, and the kind differs from capacitive element C2 used by this embodiment. Capacitive element C2 is a capacitive element in which a kind differs also from capacitive element C1 which is an MOS type capacitive element, and is a capacitive element in which a kind differs also from PIP type capacitive element C4 explained by Embodiment 5 and 6 which are mentioned later.

Thus, capacitive element C2 is a capacitive element using the capacitance between metallic pattern MP1 (first metallic pattern) and metallic pattern MP2 (second metallic pattern) which are formed in the same layer, and is a capacitive element using the capacitance between metallic pattern MP3 (first metallic pattern) and metallic pattern MP4 (second metallic pattern) which are formed in the same layer. As mentioned above, about pattern shape, metallic pattern MP1 (first metallic pattern) has the pattern shape of the comb-type with which a plurality of wiring parts MD1 (first conductor part) extending and existing to the X direction (the first direction) are connected by wiring part MC1 (first connection part) extending and existing to the Y direction (the second direction) which intersects the X direction. Metallic pattern MP2 (second metallic pattern) has the pattern shape of the comb-type with which a plurality of wiring parts MD2 (second conductor part) which extend and exist to the X direction (the first direction), and have been arranged between a plurality of wiring parts MD1 (first conductor part), respectively are connected by wiring part MC2 (second connection part) extending and existing to the Y direction (the second direction). Metallic pattern MP3 (first metallic pattern) has the pattern shape of the comb-type with which a plurality of wiring part MD4 (first conductor part) extending and existing to the X direction (the first direction) are connected by wiring part MC3 (first connection part) extending and existing to the Y direction (the second direction). Metallic pattern MP4 (second metallic pattern) has the pattern shape of the comb-type with which a plurality of wiring parts MD3 (second conductor part) which extend and exist to the X direction (the first direction), and have been arranged between a plurality of wiring parts MD4 (first conductor part), respectively are connected by wiring part MC4 (second connection part) extending and existing to the Y direction (the second direction). By making metallic patterns MP1-MP4 into such pattern shape, the capacitance value of per area (plane size) of capacitive element C2 can be enlarged efficiently. As for the wiring width (width of the Y direction) of wiring parts MD1-MD4 of metallic patterns MP1-MP4 of each wirings M2-M6, it is more preferred that it is the same as the minimum wiring width of each wirings M2-M6. Hereby, the capacitance value of per area (plane size) of capacitive element C2 can be enlarged still more efficiently.

Metallic patterns MP1-MP4 which form capacitive element C2 are formed with the wiring layer (here wirings M2-M6), or the pattern of a wiring layer formed on semiconductor substrate 1. The wiring layer (here M2-M6) is formed mainly with metal (a metallic material, the material in which metallic electrical conduction is shown) like copper or aluminum. Therefore, metallic pattern MP1, MP2, MP3, and MP4 are conductor patterns in which metallic electrical conduction is shown.

This embodiment explained the case where a plurality of wiring layers (here wirings M1-M6) were formed on semiconductor substrate 1, and metallic patterns MP1-MP4 which form capacitive element C2 were formed in wirings M2-M6 among these. However, the number of layers of the wiring with which the metallic pattern which forms capacitive element C2 is formed is not limited to this, but should just form in one or more layers of a plurality of wiring layers the metallic pattern which forms capacitive element C2. What is necessary is just to form metallic pattern MP1 and MP2 in the wiring layer, when forming only in an one-layer wiring layer the metallic pattern which forms capacitive element C2. In this case, capacitive element C2 turns into a capacitive element formed only using the capacitance between metallic pattern MP1 and MP2 of the same layer. What is necessary is to accumulate metallic pattern MP1, MP2, and metallic pattern MP3 and MP4 on the two or more-layer wiring layer by turns, and just to arrange, when forming in a two or more-layer wiring layer the metallic pattern which forms capacitive element C2. As for this, following Embodiment 2-7 is the same.

However, when forming in a two or more-layer wiring layer metallic patterns MP1-MP4 which form capacitive element C2 among a plurality of wiring layers formed on semiconductor substrate 1, the realization of high-capacity of the capacitive element C2 can be carried out more efficiently. In this case, the total capacity of capacitive element C2 becomes what applied the capacitance (it corresponds to the sixth-13th capacitance of the above in this embodiment) between the metallic patterns of a different layer (between metallic pattern MP1 and MP4 which are different as for one layer, and between metallic pattern MP2 and MP3 which are different as for one layer) to the capacitance (in this embodiment, it corresponds to the above-mentioned first-fifth capacitance) between the metallic patterns of the same layer (between metallic pattern MP1 and MP2 of the same layer, and between metallic pattern MP3 and MP4 of the same layer), further. Therefore, like this embodiment, when metallic patterns MP1-MP4 which form capacitive element C2 are formed in two or more of a plurality of wiring layers formed on semiconductor substrate 1, capacitive element C2 turns into a capacitive element formed using the capacitance between the metallic patterns of the same layer, and the capacitance between the metallic patterns of a different layer.

In the semiconductor device of this embodiment, MOS type capacitive element C1 is formed in the capacitor formation region as mentioned above of n-type semiconductor region 4, insulation film 5, upper electrode 6, and n-type semiconductor region 7. And as shown in FIG. 3-FIG. 5, wiring M1 has wiring part M1a and wiring part M1b which extend and exist to the Y direction. Wiring part M1a of wiring M1 is electrically connected to n-type semiconductor region 7 via plug 13a embedded in contact hole 12a. Wiring part M1b of wiring M1 is electrically connected to upper electrode 6 via plug 13b embedded in contact hole 12b. Since upper electrode 6 is extending and existing also directly under wiring part M1b of wiring M1, between wiring part M1b of wiring M1 and upper electrodes 6 is connectable with plug 13b. Since at least the part has overlapped with n-type semiconductor region 7 in plan view, wiring part M1a of wiring M1 can connect between n-type semiconductor region 7, and wiring part M1a of wiring M1 with plug 13a in the lap region.

Wiring part M1a of wiring M1 is extending and existing to the Y direction, and is formed (desirably with the same plane size) in the position which overlaps with wiring part MC1 of wiring M2, M4, and M6, and wiring part MC3 of wiring M3 and M5 in plan view (preferably at the same position). Wiring part M1b of wiring M1 is extending and existing to the Y direction, and is formed (desirably with the same plane size) in the position which overlaps with wiring part MC2 of wiring M2, M4, and M6, and wiring part MC4 of wiring M3 and M5 in plan view (preferably at the same position). And through hole 15, and plug 16 which fills it are arranged in the position which overlaps with wiring part MC1 of wiring M2, and wiring part M1a of wiring M1. Wiring part MC1 of wiring M2 and wiring part M1a of wiring M1 are electrically connected via this plug 16. Through hole 15, and plug 16 which fills it are arranged in the position which overlaps with wiring part MC2 of wiring M2, and wiring part M1b of wiring M1. Wiring part MC2 of wiring M2 and wiring part M1b of wiring M1 are electrically connected via this plug 16.

Therefore, the first electrode (first electrode which consists of metallic pattern MP1 and MP3 of wirings M2-M6) of capacitive element C2 is electrically connected with the lower electrode (n-type semiconductor region 4) of capacitive element C1 via plug 16, wiring part M1a of wiring M1, plug 13a, and n-type semiconductor region 7. The second electrode (second electrode which consists of metallic pattern MP2 and MP4 of wirings M2-M6) of capacitive element C2 is electrically connected to the upper electrode (upper electrode 6) of capacitive element C1 via plug 16, wiring part M1b of wiring M1, and plug 13b. For this reason, as shown also in FIG. 1, capacitive element C1 and capacitive element C2 are connected in parallel. The circuit connecting capacitive element C1 and C2 in parallel is electrically connected with an element or a bonding pad formed in other regions in a semiconductor device with wiring (not shown) of one layer or the two or more layers of wirings M1-M6 and the upper wiring layers etc. according to need.

Thus, in the semiconductor device of this embodiment, capacitive element C1 which is an MOS type capacitive element is formed in the main surface of semiconductor substrate 1. In the same plane region as having formed capacitive element C1, and in the upper layer rather than capacitive element C1, capacitive element C2 of a different kind from capacitive element C1 has been arranged, and those capacitive elements C1 and C2 are connected in parallel. That is, a plurality of capacitive elements C1 and C2 from which a kind differs mutually are accumulated on semiconductor substrate 1, are arranged, and are connected in parallel.

When aiming at realization of high-capacity of a capacitive element, generally it is thought to enlarge area of the capacitive element. For example, when aiming at realization of high-capacity of an MOS type capacitive element, the capacitance value of the MOS type capacitive element formed of a semiconductor substrate region, an upper electrode, and the insulation film between them can be enlarged by enlarging area of the upper electrode formed via an insulation film on a semiconductor substrate. However, when enlarging area of a capacitive element, the area enlargement of a semiconductor device will be caused and it will move against the flow of the area reduction (reduction of a plane size) of a semiconductor device.

So, in this embodiment, when aiming at realization of high-capacity of a capacitive element, area of the capacitive element is not enlarged. By forming the capacitive element (here, capacitive element C1 and capacitive element C2) of a different kind, and connecting these in parallel, a large capacity capacitive element is formed as total. And this capacitive element (here capacitive element C1, C2) of a different kind that did parallel connection is accumulated on semiconductor substrate 1, and is arranged in a different layer of the same plane region. Hereby, area of the plane region taken to arrange capacitive element C1 and C2 is lessened.

When capacitive element C1 and capacitive element C2 are formed in a different plane region unlike this embodiment and they are connected in parallel, the area of the plane region taken to arrange capacitive element C1 and C2 becomes large. In addition to this, the wire routing for connecting capacitive element C1 and capacitive element C2 in parallel will become long, and a parasitic resistance component will increase. Increase of this parasitic resistance component may reduce the circuit characteristics which should be formed using a capacitive element.

To it, by this embodiment, capacitive element C2 and capacitive element C1 are accumulated on the same plane region up and down, have been arranged, and they are connected in parallel. Therefore, while being able to form in a small plane region the capacitive element (capacitive element which consists of capacitive element C1 and C2 by which parallel connection was done) of big capacitance, capacitive element C1 and capacitive element C2 are connected in parallel. The wire routing for that becomes short, and a parasitic resistance component can be made small. For example, capacitive element C1 and capacitive element C2 are connectable in parallel via wiring part M1a and M1b of wiring M1, plugs 13a, 13b, and 16 connected to it, etc.

In this embodiment, a plurality of capacitive element C1 and C2 are accumulated on semiconductor substrate 1, and they are connected in parallel. By this, the total capacitance value which can be formed in the same plane region can be enlarged, and area reduction of the semiconductor device which has a capacitive element can be done. Coexistence of the realization of high-capacity of a capacitive element and the area reduction of a semiconductor device can be aimed at. Since a parasitic resistance component can be reduced, the characteristics of the circuit which connected in parallel and formed capacitive element C1 and capacitive element C2 can be improved.

And in this embodiment, a plurality of capacitive elements C1 and C2 are connected using a plurality of wiring parts (wiring part M1a of wiring M1, and wiring part MC1 and MC3 of wirings M2-M6, and wiring part M1b of wiring M1, and wiring part MC2 and MC4 of wirings M2-M6) which were formed on the semiconductor substrate and have been arranged in a mutually different layer and in the position which overlaps in plan view (preferably at the same position). Concretely, wiring part M1a of wiring M1, wiring part MC1 of wiring M2, wiring part MC3 of wiring M3, wiring part MC1 of wiring M4, wiring part MC3 of wiring M5, and wiring part MC1 of wiring M6 which are formed in a layer which is mutually different are arranged in the position which overlaps in plan view (preferably at the same position). One electrodes of capacitive element C1 and C2 are electrically connected using these. Further, wiring part M1b of wiring M1, wiring part MC2 of wiring M2, wiring part MC4 of wiring M3, wiring part MC2 of wiring M4, wiring part MC4 of wiring M5, and wiring part MC2 of wiring M6 which are formed in a mutually different layer are arranged in the position which overlaps in plan view (preferably at the same position). The electrodes of the other of capacitive element C1 and C2 are electrically connected using these. Hereby, a plurality of capacitive elements C1 and C2 are connected in parallel. By doing in this way, parallel connection of a plurality of capacitive element C1 and C2 can be done efficiently, and wire routing for connecting in parallel can be shortened more. A parasitic resistance component can be made smaller and the characteristics of the circuit which connected in parallel and formed capacitive element C1 and C2 can be improved more.

Let capacitive element C1 arranged to the most down side among a plurality of capacitive elements C1 and C2 connected in parallel be a MOS type capacitive element in this embodiment. Hereby, capacitive element C1 can be formed in a lower layer rather than the wiring structure formed on the main surface of semiconductor substrate 1. And let capacitive element C2 be the MIM type capacitive element formed using the wiring layer (here, wirings M2-M6) of comparatively a lower layer. Hereby, capacitive element C2 can be formed in the same plane region as capacitive element C1 and in the upper layer rather than capacitive element C1. For this reason, arranging capacitive element C1 and C2 of a different kind in a different layer of the same plane region can be realized easily.

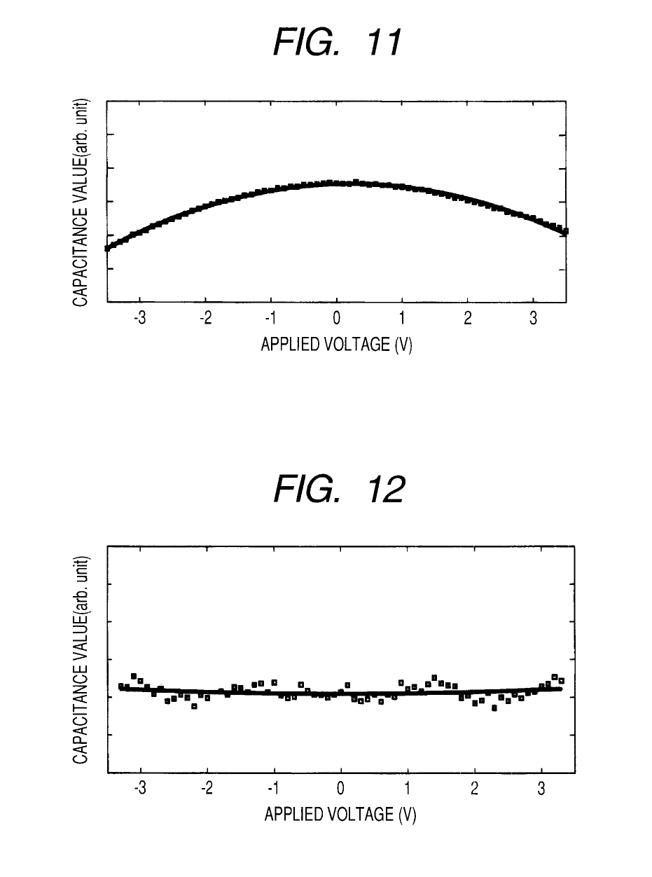

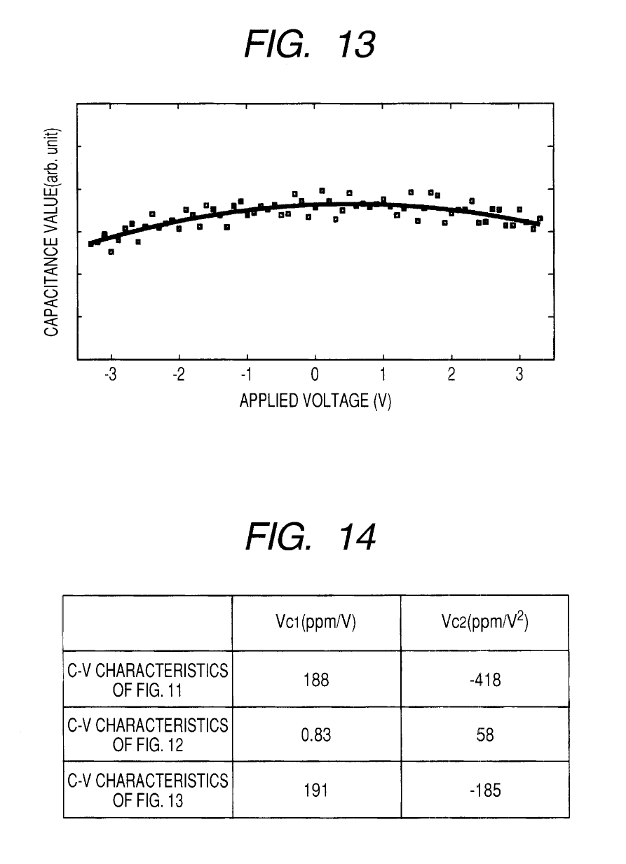

FIG. 11 is a graph which shows an example of C-V (capacitance-voltage) characteristics of a single MOS type capacitive element like capacitive element C1. FIG. 12 is a graph which shows an example of C-V characteristics of a single MIM type capacitive element using a comb-type wiring pattern like capacitive element C2. FIG. 13 is a graph which shows an example of the C-V characteristics of the circuit of structure of having done parallel connection of an MOS type capacitive element like capacitive element C1, and a MIM type capacitive element using a comb-type wiring pattern like capacitive element C2 like the semiconductor device of this embodiment. The horizontal axis of the graph of FIG. 11-FIG. 13 corresponds to the voltage applied between the electrodes of a capacitive element, and the vertical axis of the graph of FIG. 11-FIG. 13 corresponds to a capacitance value. The unit of the vertical axis of FIG. 11-FIG. 13 is an arbitrary unit (arb.unit). The scale (gap of a graduation) is the same at FIG. 11-FIG. 13, and the region of a different capacitance value is shown in the vertical axis of FIG. 11-FIG. 13. FIG. 14 is a table showing the voltage coefficient (V_{C1}, V_{C2}) of the C-V characteristics of FIG. 11-FIG. 13. The graph of the C-V characteristics of FIG. 11-FIG. 13 can be approximated with a following formula using coefficients a and b.

C=b×V²+a×V+V_{C0}

C in the formula is a capacitance value corresponding to the vertical axis of FIG. 11-FIG. 13 here, and V in the formula is the voltage value corresponding to the horizontal axis of FIG. 11-FIG. 13. V_{C0} is a capacitance value at the time of voltage zero.

Modification of the above-mentioned formula will obtain the following formula.

C=(1+a/V_{C0}×V+b/V_{C0}×V²)×V_{C0}

When expressed as V_{C1}=a/V_{C0} and V_{C2}=b/V_{C0} here,

C=(1+V_{C1}×V+V_{C2}×V²)×V_{C0}

Here, the above-mentioned V_{C1} is equivalent to the first coefficient (coefficient of the first power of voltage V) of voltage, and the above-mentioned V_{C2} is equivalent to the secondary coefficient (coefficient of the square of voltage V) of voltage.

An MOS type capacitive element like capacitive element C1 has the advantage that a large capacity capacitive element is realizable in a comparatively small area from the ability of thickness of a capacitance insulation film (here insulation film 5) to be made thin. However, as shown also in FIG. 11 and FIG. 14, the voltage dependency of a capacitance value is large (C-V characteristics are not flats). For this reason, in a single MOS type capacitive element, it is hard to realize capacitance independent of a bias voltage value.

On the other hand, compared with an MOS type capacitive element, a MIM type capacitive element using a comb-type wiring pattern like capacitive element C2 has the small voltage dependency of a capacitance value, as shown also in FIG. 12 and FIG. 14. Further, as for capacitive element C1 which is an MOS type capacitive element, as is shown in FIG. 11, (a graph of) C-V characteristics become convex-like to upward. As for capacitive element C2 which is a MIM type capacitive element using a comb-type wiring pattern, as is shown in FIG. 12, (a graph of) C-V characteristics become convex-like to downward. Both differ in the direction of C-V characteristics (voltage dependency of capacitance). As is understood also from the table of FIG. 14, this is because the secondary coefficient (it corresponds to the above-mentioned V_{C2}) of the voltage of the C-V characteristics (it corresponds to FIG. 11) of capacitive element C1 which is an MOS type capacitive element is negative (namely, V_{C2}<0), and the secondary coefficient (it corresponds to the above-mentioned V_{C2}) of the voltage of the C-V characteristics (it corresponds to FIG. 12) of MIM type capacitive element C2 using a comb-type wiring pattern is positive (namely, V_{C2}>0). Thus, although a kind differs between capacitive element C1 and capacitive element C2 mutually, they are capacitive elements from which characteristics (C-V characteristics, i.e., voltage dependency of capacitance) also differ.

In the semiconductor device of this embodiment, capacitive element C2 (MIM type capacitive element using a comb-type wiring pattern) which has different characteristics (C-V characteristics) from capacitive element C1 has been accumulated and arranged on an MOS type capacitive element like capacitive element C1, and they are connected in parallel. That is, in the capacitor formation region of semiconductor substrate 1, a plurality of capacitive element C1 and C2 from which characteristics (C-V characteristics) differ mutually are accumulated on semiconductor substrate 1, and are connected in parallel. Hereby, in this embodiment, compared with the case of a single MOS type capacitive element, total capacitance can be enlarged, and as shown also in FIG. 13 and FIG. 14, the voltage dependency of a capacitance value becomes small (namely, C-V characteristics become flat). The capacitive element which is large capacity and does not depend on a bias voltage value is realizable. Especially, as FIG. 14 also shows, as compared with an MOS type capacitive element single case (it corresponds to the column of the “C-V characteristics of FIG. 11” in the table of FIG. 14), in the case of this embodiment (it corresponds to the column of the “C-V characteristics of FIG. 13” in the table of FIG. 14), the above-mentioned V_{C2} which is a secondary coefficient of voltage is improvable (that is, the absolute value of V_{C2} becomes small). Therefore, in this embodiment, the capacitance value of per a plane size (area) of the capacitor formation region occupied to a semiconductor device can be enlarged. It becomes difficult for a capacitance value to depend on a bias voltage value, and it can improve the characteristics of a circuit using a capacitive element. The capacitive element (capacitive element which consists of capacitive element C1 and C2 by which parallel connection was done) which has flat C-V characteristics (C-V characteristics that voltage dependency is small), with large capacity in total is realizable.

In this embodiment, the capacitive element of the undermost layer is used as capacitive element C1 which is an MOS type capacitive element among a plurality of capacitive elements which accumulate on the same plane region (a different layer), arrange, and do parallel connection. Therefore, capacitive element C1 can be formed at the almost same step as MISFET formed in other regions (MISFET formation region) of semiconductor substrate 1, and the number of manufacturing processes of a semiconductor device can be reduced. Therefore, it is more effective, when capacitive element C1 is used by this embodiment, and the following embodiments and it applies to the semiconductor device with which MISFET is formed in other regions (regions other than the capacitor formation region in which capacitive element C1 was formed) of semiconductor substrate 1.

That a capacitance value becomes the most large when a plane size is the same among capacitive element C1, C2, and capacitive element C3 and C4 that are explained by the below-mentioned embodiment is capacitive element C1 which is easy to make a capacitance insulation film the thinnest. For this reason, when using the capacitive element of an undermost layer as capacitive element C1 which is an MOS type capacitive element like this embodiment among a plurality of capacitive elements which accumulate, arrange and do parallel connection, the capacitive element of a bigger capacitance value can be formed in a small capacitor formation region.

### Embodiment 2

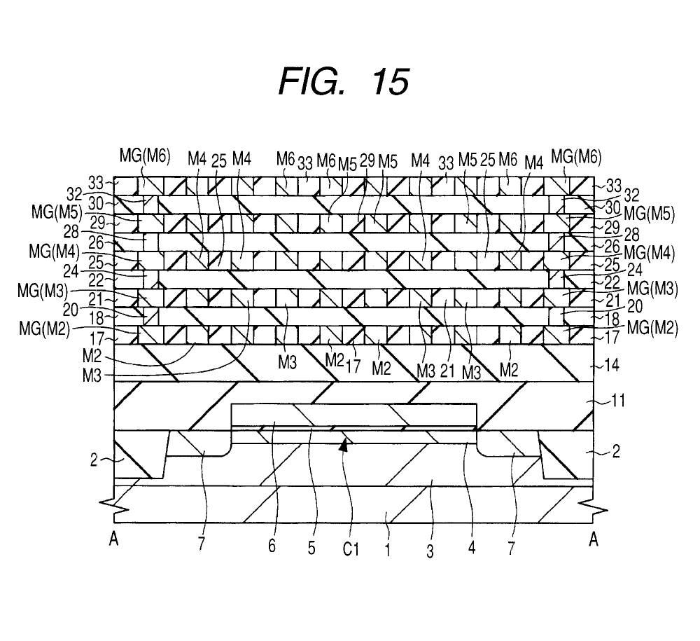

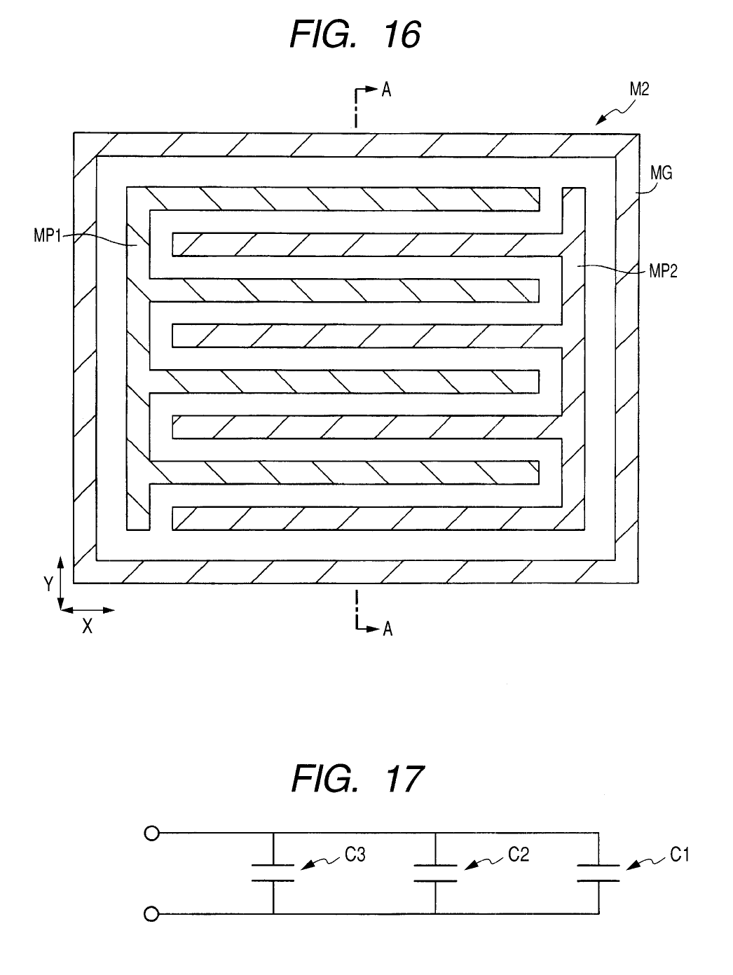

FIG. 15 is a principal part cross-sectional view of the semiconductor device of this embodiment, and FIG. 16 is a principal part plan view of the semiconductor device of this embodiment. FIG. 15 corresponds to the FIG. 2 of above-mentioned Embodiment 1, and FIG. 16 corresponds to the FIG. 6 of above-mentioned Embodiment 1. Therefore, the section of the A-A line of FIG. 16 corresponds to FIG. 15.

In this embodiment, as shown in FIG. 15, wiring part MG for a shield which consists of wirings M2-M6 is provided so that wirings (namely, metallic pattern MP1, MP2, MP3, MP4 which were explained by above-mentioned Embodiment 1) M2-M6 which form capacitive element C2 may be surrounded in a capacitor formation region.

The layout of wiring M2 of a capacitor formation region is shown in FIG. 16. Wiring part MG which consists of wiring M2 is formed so that metallic pattern MP1 and MP2 of wiring M2 may be surrounded in plan view. Wiring part MG is similarly formed with wirings M3-M6.

That is, wiring part MG which consists of wiring M3 is formed so that metallic pattern MP3 and MP4 of wiring M3 may be surrounded. Wiring part MG which consists of wiring M4 is formed so that metallic pattern MP1 and MP2 of wiring M4 may be surrounded in plan view. Wiring part MG which consists of wiring M5 is formed so that metallic pattern MP3 and MP4 of wiring M5 may be surrounded. Wiring part MG which consists of wiring M6 is formed so that metallic pattern MP1 and MP2 of wiring M6 may be surrounded in plan view. Each wiring part MG of wirings M2-M6 is formed in the position which overlaps in plan view (preferably at the same position), and they are electrically mutually connected via plugs 20, 24, 28, and 32. Wiring part MG is connected to fixed potential (preferably grounding electric potential or ground potential).

In this embodiment, in addition to the effect acquired by above-mentioned Embodiment 1, capacitive element C2 can be further shielded in electromagnetism by having formed wiring part MG. Hereby, the characteristics of a circuit of having connected capacitive element C1 and C2 in parallel can be improved more. Also in following Embodiment 3-6, the same wiring part MG as this embodiment can be formed, and the same effect can be acquired.

### Embodiment 3

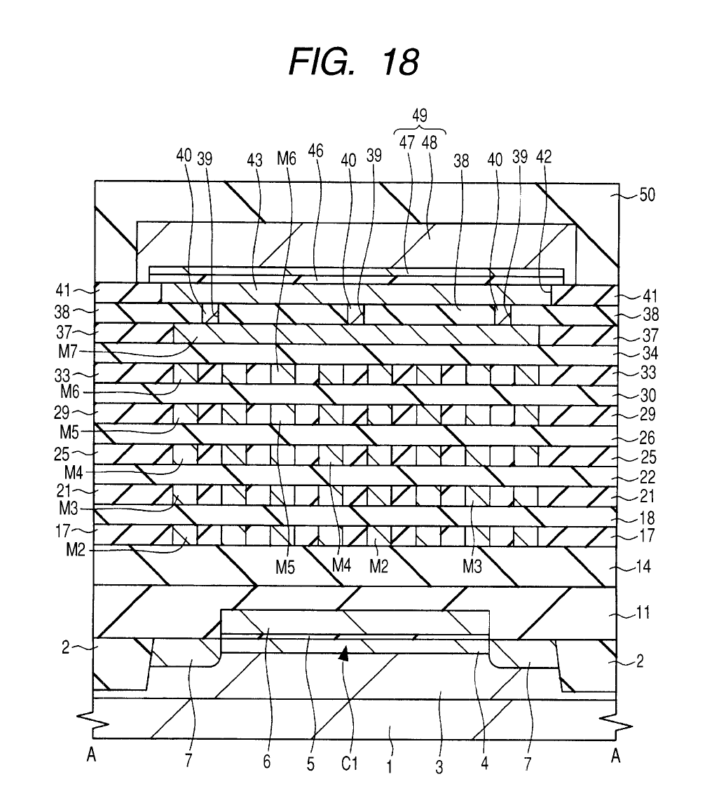

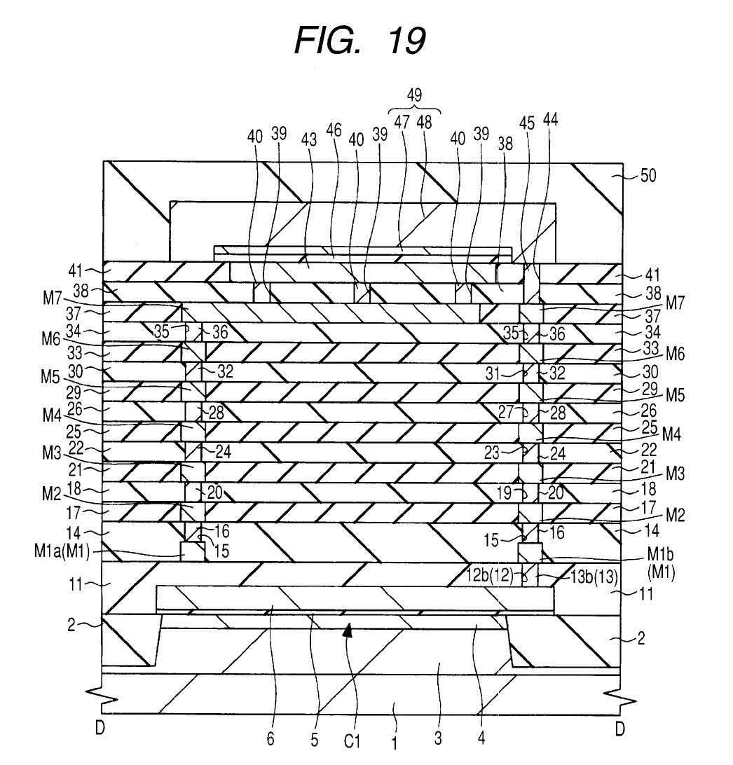

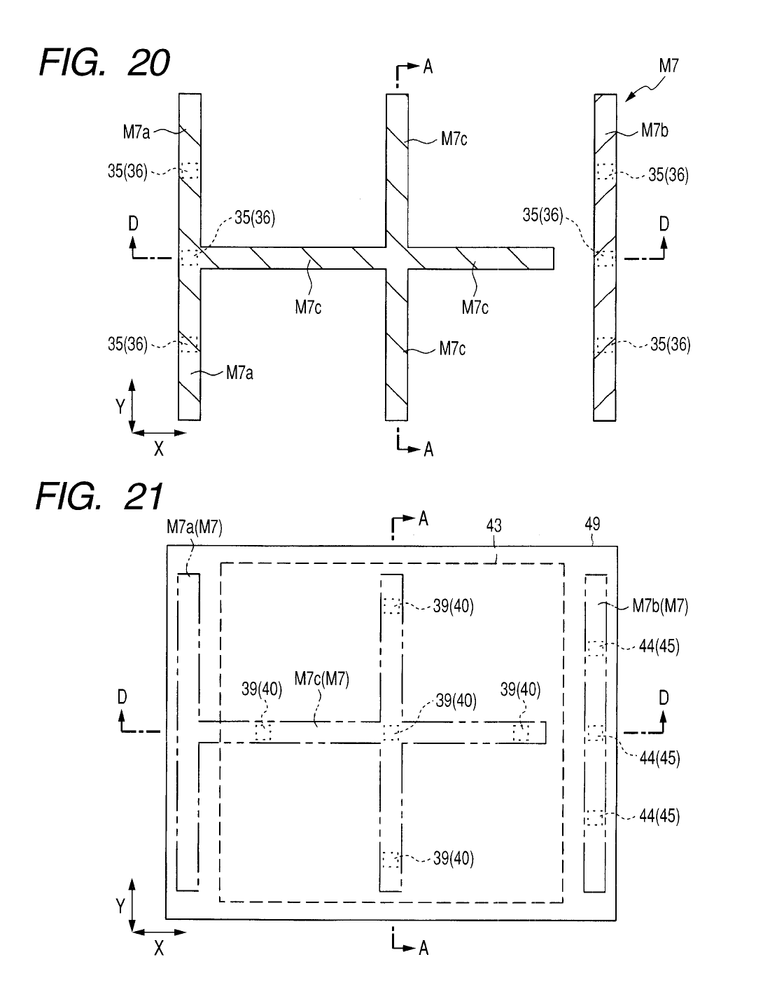

FIG. 17 is a principal part circuit diagram of the semiconductor device of this embodiment. FIG. 18 and FIG. 19 are the principal part cross-sectional views of the semiconductor device of this embodiment. FIG. 20 and FIG. 21 are the principal part plan views of the semiconductor device of this embodiment.

FIG. 17 corresponds to the FIG. 1 of above-mentioned Embodiment 1, and the circuit (equivalent circuit) formed in the capacitor formation region of a semiconductor device shown in FIG. 18-FIG. 21 is shown. As for FIG. 18 and FIG. 19, the cross-sectional view of the capacitor formation region of a semiconductor device is shown, and FIG. 18 corresponds to the FIG. 2 of above-mentioned Embodiment 1. In FIG. 20 and FIG. 21, the same plane position (capacitor formation region) as the FIG. 5-FIG. 10 of above-mentioned Embodiment 1 is shown. The plane layout of wiring M7 which is seventh layer wiring is shown in FIG. 20. Although it is a plan view, in order to make a drawing legible, hatching is given to wiring M7. Lower electrode 43 and upper electrode 49 of capacitive element C3, and the plane layout of wiring M7 are shown in FIG. 21. The section of the A-A line of FIG. 20 and FIG. 21 corresponds to FIG. 18, and the section of a D-D line corresponds to FIG. 19. Also in this embodiment, since the plane layout of n-type semiconductor region 4, upper electrode 6, n-type semiconductor region 7, contact hole 12 (12a, 12b), and wirings M1-M6 is the same as that of the FIG. 5-FIG. 10 of above-mentioned Embodiment 1, the illustration is omitted here.

Since insulation film 33 where wiring M6 was embedded, and the structure below it of the semiconductor device of this embodiment are the same as that of the semiconductor device of above-mentioned Embodiment 1, the explanation is omitted and the structure above insulation film 33 where wiring M6 was embedded is explained here.

In this embodiment, as shown in FIG. 18 and FIG. 19, on insulation film 33 where wiring M6 was embedded, insulation film (interlayer insulation film) 34 is formed. Through hole (an opening, a hole) 35 is formed in insulation film 34. In through hole 35, plug (a conductor part, the conductor part for connection) 36 is formed and embedded. Plug 36 is electrically connected in contact with wiring M6 at the bottom.

On insulation film 34 where plug 36 was embedded, insulation film (interlayer insulation film) 37 is formed. A wiring groove, and wiring M7 embedded in this wiring groove are formed in this insulation film 37. Wiring M7 is the seventh layer wiring (wiring layer) of one upper layer from wiring M6. Wiring M7 has a pattern as shown in FIG. 20 in the capacitor formation region. Wiring M7 can be formed using damascene technology (here single damascene technology), and can be the copper wiring which uses copper as a principal component. Wiring M7 can also be formed using dual damascene technology, and wiring M7 and plug 36 are formed in one in this case. In order to make small parasitic capacitance between wiring M7 and wiring M6, it is more preferred to make thickness of insulation film 34 thicker than each thickness of insulation films 18, 22, 26, and 30.

Wiring M7 is formed mainly with metal (a metallic material, the material in which metallic electrical conduction is shown) like copper. When wiring M7 is an embedded wiring formed by the damascene method like this embodiment, it is more preferred. However, wiring M7 can also be set as the wiring (for example, aluminum wiring) formed by patterning of the conductor film (metallic film) as other forms.

On insulation film 37 where wiring M7 was embedded, insulation film (interlayer insulation film) 38 is formed. Through hole (an opening, a hole) 39 is formed in insulation film 38, and plug (a conductor part, the conductor part for connection) 40 is formed and embedded in through hole 39. Plug 40 is electrically connected in contact with wiring M7 at the bottom.

On insulation film 38 where plug 40 was embedded, insulation film (interlayer insulation film) 41 is formed. Opening 42 for lower electrodes is formed in insulation film 41, and lower electrode 43 for capacitive element C3 (a metal electrode, a lower metal electrode) is formed and embedded in this opening 42 for lower electrodes. Lower electrode 43 is electrically connected in contact with plug 40 at the bottom.

Through hole (an opening, a hole) 44 is formed in insulation films 38 and 41, and plug (a conductor part, the conductor part for connection) 45 is formed and embedded in through hole 44. Plug 45 is electrically connected in contact with wiring M7 at the bottom.

For example, lower electrode 43 and plug 45 can be formed, after forming opening 42 for lower electrodes, and through hole 44, by forming the conductor film which consists of tungsten etc. so that these may be filled, and removing the conductor film on insulation film 41 by the CMP method or the etch back method. Although lower electrode 43 can be formed using single damascene technology, lower electrode 43 can also be formed using dual damascene technology as other forms, and lower electrode 43 and plug 40 are formed in one in this case. When forming lower electrode 43 and plug 45 at the same step, since the number of manufacturing processes can be reduced, it is more desirable, but lower electrode 43 and plug 45 can also be formed at a separate step.

Insulating film 46 is formed on insulation film 41 comprising lower electrode 43 upper part, conductor film 47 is formed on insulation film 46, and conductor film 48 is formed on conductor film 47. Upper electrode 49 for capacitive element C3 (a metal electrode, an upper metal electrode) is formed by conductor film 47 and conductor film 48.

Insulating film 46 consists of a patterned insulation film, and consists of a silicon nitride film etc., for example. Conductor film 47 consists of a patterned conductor film, and consists of titanium, titanium nitride, tungsten, or tungsten nitride, for example. Conductor film 48 consists of a patterned conductor film, and consists of a conductor film (an aluminum film or an aluminum alloy film) which uses aluminum as a principal component, for example. Conductor film 48 can also be made into the laminated film of a main conductor film, and the barrier conductor film formed in the upper surface, under surface, or up-and-down both faces of the main conductor film. As the main conductor film of conductor film 48, the main conductor film which uses aluminum as a principal component, for example can be used. As the barrier conductor film of conductor film 48, a titanium film, titanium nitride films, or those laminated films can be used, for example.

The laminated film which turns into insulation film 46 and conductor film 47 later is formed on the whole surface of insulation film 41 comprising lower electrode 43 upper part. Then, this laminated film is patterned. Then, the conductor film which turns into conductor film 48 later is formed on the whole surface of insulation film 41 comprising laminated film upper part of insulation film 46 and conductor film 47. Then, insulation film 46, and conductor films 47 and 48 can be formed by patterning this conductor film.

With upper electrode 49 which consists of conductor films 47 and 48, lower electrode 43, and insulation film 46 between lower electrode 43 and upper electrode 49, MIM (Metal insulator Metal) type capacitive element C3 is formed in a capacitor formation region. Lower electrode 43 and upper electrode 49 are metal electrodes which consist of metal (a metallic material, the material in which metallic electrical conduction is shown). Lower electrode 43 turns into one electrode (lower electrode) of capacitive element C3, and upper electrode 49 turns into the other electrode (upper electrode) of capacitive element C3. Insulating film 46 located between lower electrode 43 and upper electrode 49 turns into a capacitance insulation film (dielectric film) of capacitive element C3. Insulating film 46 and upper electrode 49 are formed so that they may comprise (include) lower electrode 43 in plan view as FIG. 21 also shows. When forming conductor film 47, since the damage to insulation film 46 at the time of patterning can be prevented, it is more desirable, but formation of conductor film 47 is also omissible. When formation of conductor film 47 is omitted, conductor film 48 is formed so that the upper surface of insulation film 46 may be touched, and this conductor film 48 constitutes upper electrode 49.

Capacitive element C3 is a capacitive element using the capacitance between the upper metal electrode (the metaled upper electrode, here upper electrode 49) and lower metal electrode (the metaled lower electrode, here lower electrode 43) which have been arranged up and down via an insulation film. That is, capacitive element C3 is a capacitive element using the capacitance between a lower metal electrode (lower electrode 43), and the upper metal electrode on the lower metal electrode (here upper electrode 49). Capacitive element C3 is a capacitive element which does not use the capacitance between the metallic patterns of the same layer unlike capacitive element C2. For this reason, capacitive element C3 is a capacitive element in which a kind differs from capacitive element C2. Capacitive element C3 is a capacitive element in which a kind differs also from capacitive element C1 which is an MOS type capacitive element. Capacitive element C3 is a capacitive element in which a kind differs also from PIP type capacitive element C4 explained by Embodiment 5 and 6 which are mentioned later.

On insulation film 41, insulation film (surface protection film) 50 as a protective film of the top layer is formed so that upper electrode 49 may be covered.

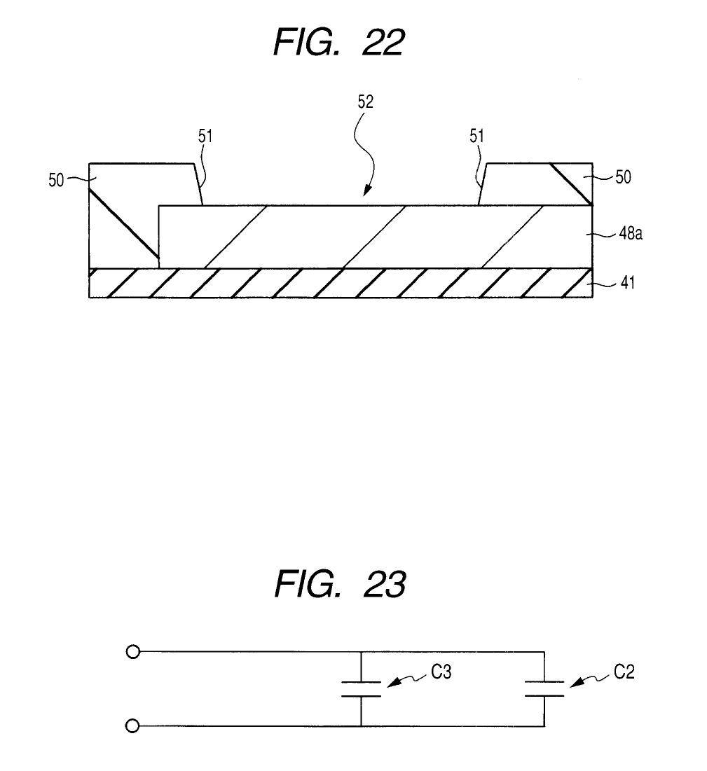

Conductor film 48 is formed using the conductor film of the same layer as the conductor film for bonding pad formation (conductor film 48a mentioned later). FIG. 22 is a principal part cross-sectional view of other regions of the semiconductor device of this embodiment, and the bonding pad formation region is shown. In FIG. 22, illustration of the structure below insulation film 41 is omitted.

As shown in FIG. 22, opening 51 for bonding pads is formed in insulation film 50. A part of conductor film 48a is exposed from opening 51, and bonding pad (pad electrode) 52 is formed.

Conductor film 48a for bonding pads and conductor film 48 for upper electrode 49 are metallic films (conductor film) of the same layer, and they are formed together (simultaneously). That is, the same metallic film (conductor film) for conductor films 48 and 48a is formed on insulation film 41, and this metallic film (conductor film) is patterned. By this, conductor film 48a for bonding pads, and conductor film 48 for upper electrode 49 can be formed together (simultaneously). In order to make easy wire bonding to bonding pad 52, a plating film etc. can also be formed on conductor film 48a exposed from opening 51. A bump electrode can also be formed on bonding pad 52.

Thus, upper electrode 49 of capacitive element C3 is formed using the metal layer (here conductor film 48) of the same layer as the metal layer (here conductor film 48a) for the bonding pad electrodes (here bonding pad 52) of the semiconductor device.

As shown in FIG. 20, in the capacitor formation region, wiring M7 has wiring part M7a formed (desirably with the same size) in the position (preferably in the same position) which overlaps in plan view to wiring part M1a of wiring M1, and wiring part MC1 of wiring M2, M4, and M6 and wiring part MC3 of wiring M3 and M5. Further, in the capacitor formation region, wiring M7 has wiring part M7b formed (desirably with the same size) in the position (preferably in the same position) which overlaps in plan view to wiring part M1b of M1, and wiring part MC2 of wiring M2, M4, and M6 and wiring part MC4 of wiring M3 and M5. Further, in the capacitor formation region, wiring M7 has wiring part M7c extending and existing under lower electrode 43 of capacitive element C3. Wiring part M7c is connected to wiring part M7a, and wiring part M7a and wiring part M7c have become the pattern formed in one.

A layer differs between wiring M7 and lower electrode 43, and lower electrode 43 is arranged at the upper layer rather than wiring M7. When seeing in plan view (when seeing at a plane parallel to the main surface of semiconductor substrate 1), as shown in FIG. 21, lower electrode 43 is arranged between wiring part 7a and wiring part 7b of wiring M7. And lower electrode 43 is a pattern (large area pattern) which has a bigger size (side) than the wiring width (the width or the size of the Y direction of wiring parts MD1-MD4) of metallic patterns MP1-MP4 of wirings M2-M6 which form capacitive element C2. When the plane form of lower electrode 43 is the quadrangular shape which has sides parallel to the X direction and the Y direction, since lower electrode 43 can be efficiently arranged between wiring part 7a and wiring part 7b of wiring M7, and the capacitance value of capacitive element C3 can be enlarged, it is more preferred. And upper electrode 49 of capacitive element C3 is a pattern (a pattern of a larger area than lower electrode 43) of a further large area which includes lower electrode 43 in plan view. Although upper electrode 49 extends and exists right above wiring part M7b of wiring M7, lower electrode 43 does not extend and does not exist. Between wiring part M7b of wiring M7 and upper electrodes 49 is connectable with plug 45.

Through hole 39, and plug 40 which fills it are arranged in the position which overlaps with lower electrode 43, and wiring part M7c of wiring M7 in plan view. Lower electrode 43 of capacitive element C3 is electrically connected to wiring part M7c of wiring M7 via this plug 40. And through hole 35, and plug 36 which fills it are arranged in the position which overlaps with wiring part M7a of wiring M7, and wiring part MC1 of wiring M6 in plan view. Wiring part M7a of wiring M7 is electrically connected to wiring part MC1 of wiring M6 via this plug 36. Therefore, via plug 40, wiring part M7c and M7a of wiring M7, and plug 36, lower electrode 43 of capacitive element C3 electrically connects with the first electrode (first electrode which consists of metallic pattern MP1 and MP3 of wirings M2-M6) of capacitive element C2, and electrically connects also with the lower electrode (n-type semiconductor region 4) of capacitive element C1 further.

Through hole 44, and plug 45 which fills it are arranged in the position which overlaps with upper electrode 49, and wiring part M7b of wiring M7 in plan view. Upper electrode 49 of capacitive element C3 is electrically connected to wiring part M7b of wiring M7 via this plug 45. And through hole 35, and plug 36 which fills it are arranged in the position which overlaps with wiring part M7b of wiring M7, and wiring part MC2 of wiring M6 in plan view. Wiring part M7b of wiring M7 is electrically connected to wiring part MC2 of wiring M6 via this plug 36. Therefore, via plug 45, wiring part M7b of wiring M7, and plug 36, upper electrode 49 of capacitive element C3 electrically connects with the second electrode (second electrode which consists of metallic pattern MP2 and MP4 of wirings M2-M6) of capacitive element C2, and electrically connects also with the upper electrode (upper electrode 6) of capacitive element C1 further.

Therefore, as shown also in FIG. 17, capacitive element C1, capacitive element C2, and capacitive element C3 are connected in parallel. The circuit which connected with capacitive element C1, C2, and C3 in parallel electrically connects with the element formed in other regions in a semiconductor device, or the bonding pad according to need with the wiring (not shown) of one layer or two or more layers among wirings M1-M7 etc.

In above-mentioned Embodiment 1, in the capacitor formation region, capacitive element C1 was formed in the main surface of semiconductor substrate 1, capacitive element C2 which is a capacitive element of a different kind from capacitive element C1 was formed above (right above) capacitive element C1, and capacitive element C1 and capacitive element C2 were connected in parallel. In this embodiment, capacitive element C1 is formed in the main surface of semiconductor substrate 1 in a capacitor formation region, capacitive element C2 which is a capacitive element of a different kind from capacitive element C1 is formed above capacitive element C1, and capacitive element C3 which is a capacitive element of a different kind from capacitive element C1 and C2 was formed above (right above) capacitive element C2, and capacitive element C1, capacitive element C2, and capacitive element C3 are connected in parallel. That is, in this embodiment, a plurality of capacitive element C1, C2, and C3 from which a kind differs mutually are accumulated on semiconductor substrate 1, are arranged, and they are connected in parallel. Therefore, a plurality of capacitive elements C1, C2, and C3 are arranged at a different layer of the same plane region. Although a kind differs among capacitive element C1, capacitive element C2, and capacitive element C3 mutually, they are a capacitive element from which characteristics (C-V characteristics, i.e., voltage dependency of capacitance) also differ. For this reason, in this embodiment, a plurality of capacitive elements C1, C2, and C3 from which characteristics differ mutually are accumulated on semiconductor substrate 1, are arranged, and they are connected in parallel.

In this embodiment, capacitive element C3 has been further arranged on capacitive elements C1 and C2 in addition to capacitive elements C1 and C2, and these capacitive elements C1, C2, and C3 are connected in parallel. So, in addition to the effect acquired by above-mentioned Embodiment 1, the capacitive element (capacitive element which consists of capacitive element C1, C2, and C3 by which parallel connection was done) which is further large capacity can be formed in a small plane region. For this reason, it becomes very advantageous to the area reduction of a semiconductor device which has a capacitive element. It becomes very advantageous to coexistence of the realization of high-capacity of a capacitive element, and the area reduction of a semiconductor device.

In this embodiment, a plurality of capacitive elements C1, C2, and C3 are connected using a plurality of wiring parts (wiring part M1a of wiring M1, wiring part MC1 and MC3 of wirings M2-M6, and wiring part M7a of wiring M7, and wiring part M1b of wiring M1, wiring part MC2 and MC4 of wirings M2-M6, and wiring part M7b of wiring M7) which were formed on the semiconductor substrate and which are mutually different layers and have been arranged in the position which overlaps in plan view. Concretely, wiring part M1a of wiring M1, wiring part MC1 of wiring M2, wiring part MC3 of wiring M3, wiring part MC1 of wiring M4, wiring part MC3 of wiring M5, wiring part MC1 of wiring M6, and wiring part M7a of wiring M7 which were formed in layers which are mutually different are arranged in the position (preferably in the same position) which overlaps in plan view. One electrodes of capacitive elements C1, C2, and C3 are electrically connected using these. Further, wiring part M1b of wiring M1, wiring part MC2 of wiring M2, wiring part MC4 of wiring M3, wiring part MC2 of wiring M4, wiring part MC4 of wiring M5, wiring part MC2 of wiring M6, and wiring part M7b of wiring M7 which were formed in a mutually different layer are arranged in the position (preferably in the same position) which overlaps in plan view. The other electrodes of capacitive elements C1, C2, and C3 are connected using these. Hereby, a plurality of capacitive elements C1, C2, and C3 are connected in parallel. By doing in this way, parallel connection of a plurality of capacitive elements C1, C2, and C3 can be done efficiently, and wire routing for connecting in parallel can be shortened more. A parasitic resistance component can be made smaller and the characteristics of the circuit which connected capacitive element C1, C2, and C3 in parallel, and was formed can be improved more.

### Embodiment 4

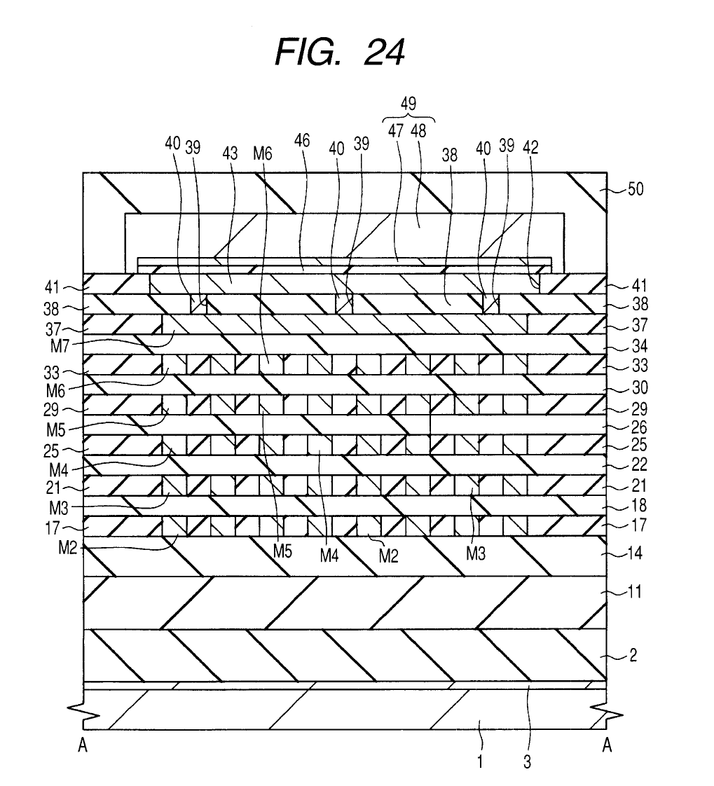

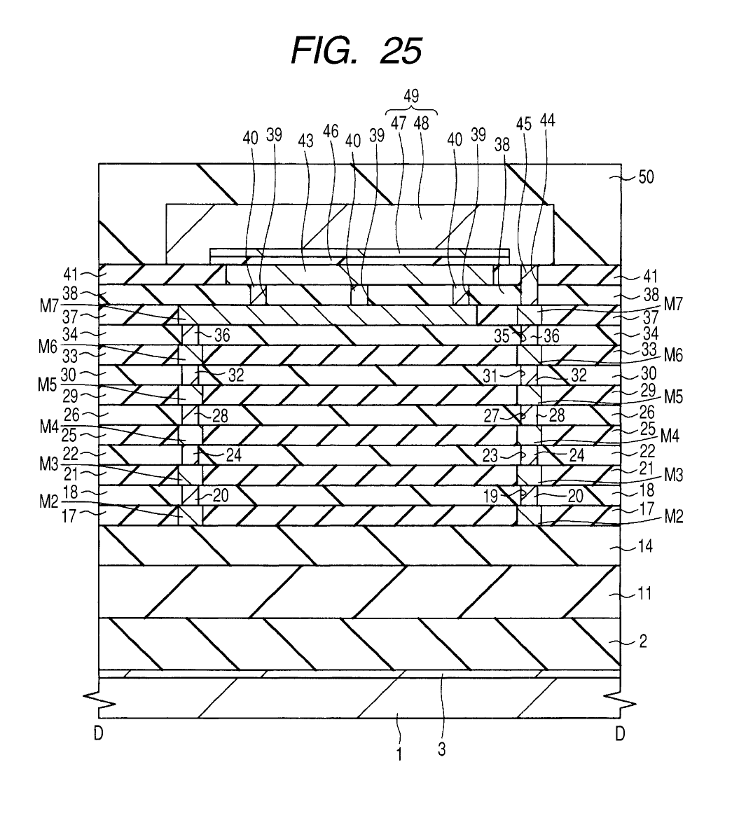

FIG. 23 is a principal part circuit diagram of the semiconductor device of this embodiment, and corresponds to the FIG. 18 of above-mentioned Embodiment 3. FIG. 24 and FIG. 25 are the principal part cross-sectional views of the semiconductor device of this embodiment, and correspond to the FIG. 18 and FIG. 19 of above-mentioned Embodiment 3, respectively.

In above-mentioned Embodiment 3, capacitive element C1, C2, and C3 were formed in the capacitor formation region. However, in this embodiment, formation of capacitive element C1 is omitted and capacitive elements C2 and C3 are formed in a capacitor formation region.

In this embodiment, as shown in FIG. 24 and FIG. 25, element isolation region 2 is formed in semiconductor substrate 1 in the whole capacitor formation region. And, as for n-type semiconductor region 4, insulation film 5, upper electrode 6, n-type semiconductor region 7, contact holes 12a and 12b, and plugs 13a and 13b which were formed by above-mentioned Embodiment 3 (wiring part M1a and M1b as well, if unnecessary) in a capacitor formation region, the formation is omitted in this embodiment. Since other structures of the semiconductor device of this embodiment is the same as that of the semiconductor device of above-mentioned Embodiment 3 almost, the detailed explanation is omitted here.

In this embodiment, a plurality of capacitive elements C2 and C3 from which a kind differs mutually are accumulated on semiconductor substrate 1, are arranged, and they are connected in parallel. Although a kind differs between capacitive element C2 and capacitive element C3 mutually, they are a capacitive element from which characteristics (C-V characteristics, i.e., voltage dependency of capacitance) also differ. For this reason, in this embodiment, a plurality of capacitive elements C2 and C3 from which characteristics differ mutually are accumulated on semiconductor substrate 1, are arranged, and they are connected in parallel.

In this embodiment, a plurality of capacitive elements C2 and C3 are accumulated and arranged on (a different layer of) the same plane region, and parallel connection is done. Hereby, a large capacity capacitive element (capacitive element which consists of capacitive elements C2 and C3 by which parallel connection was done) can be formed in a small plane region. For this reason, area reduction of the semiconductor device which has a capacitive element can be done. Coexistence of the realization of high-capacity of a capacitive element and the area reduction of a semiconductor device can be aimed at.

When compared with the above-mentioned capacitive element C1, and capacitive element C4 explained by below-mentioned Embodiment 5 and 6, C-V characteristics are close to a flat (the voltage dependency of a capacitance value is small), and electrical property is good as to capacitive element C2 and C3 which were formed with the metallic pattern. This embodiment is accumulating a plurality of capacitive elements C2 and C3, and connecting in parallel, and forms a large capacity capacitive element in a small plane region. It becomes difficult for a capacitance value to depend on a bias voltage value by using only capacitive elements C2 and C3 which are easy to make voltage dependency of a capacitance value small. The characteristics of a circuit using a capacitive element can be improved most. Therefore, the capacitive element (capacitive element which consists of capacitive elements C2 and C3 by which parallel connection was done) which is large capacity in total and has the flattest C-V characteristics (C-V characteristics that voltage dependency is small) is realizable.

In a capacitor formation region, under capacitive element C2 formed with (metallic patterns MP1-MP4 of) wirings M2-M6, as for transistor elements, such as MISFET, when interference is taken into consideration, not forming is preferred. However, when forming transistor elements, such as MISFET, under capacitive element C2, it is preferred to form the large area pattern of wiring M1 between the transistor element and capacitive element C2, and to shield a transistor element from capacitive element C2.

### Embodiment 5

Although capacitive elements C1 and C2 were formed in the capacitor formation region in above-mentioned Embodiment 1, PIP type capacitive element C4 is formed instead of MOS type capacitive element C1 in this embodiment.

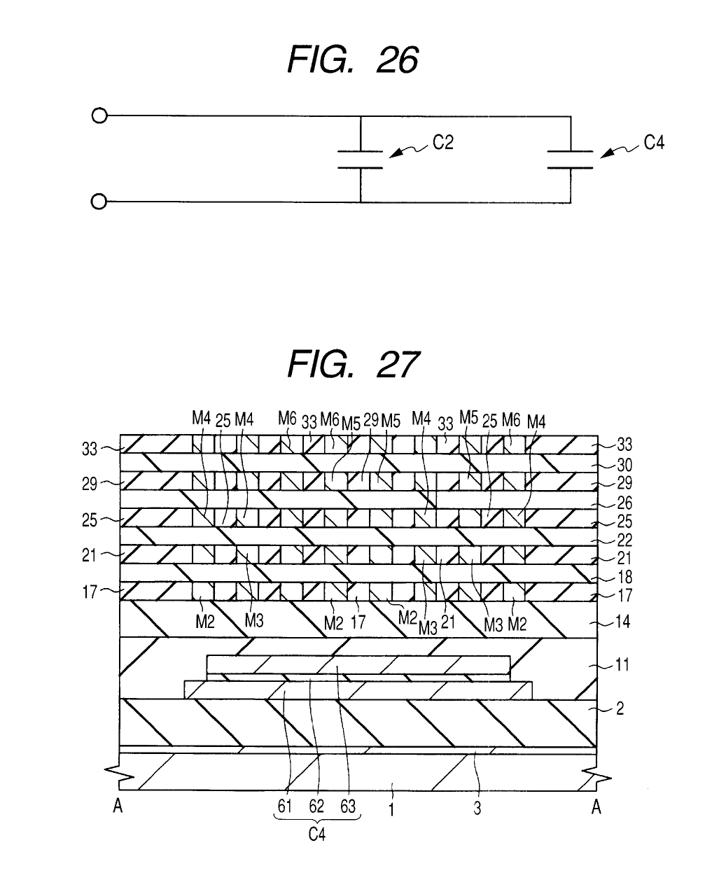

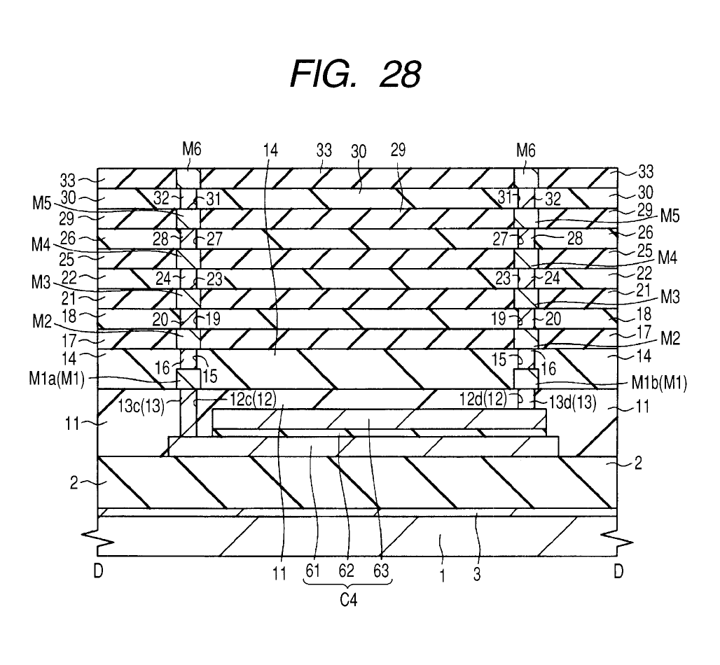

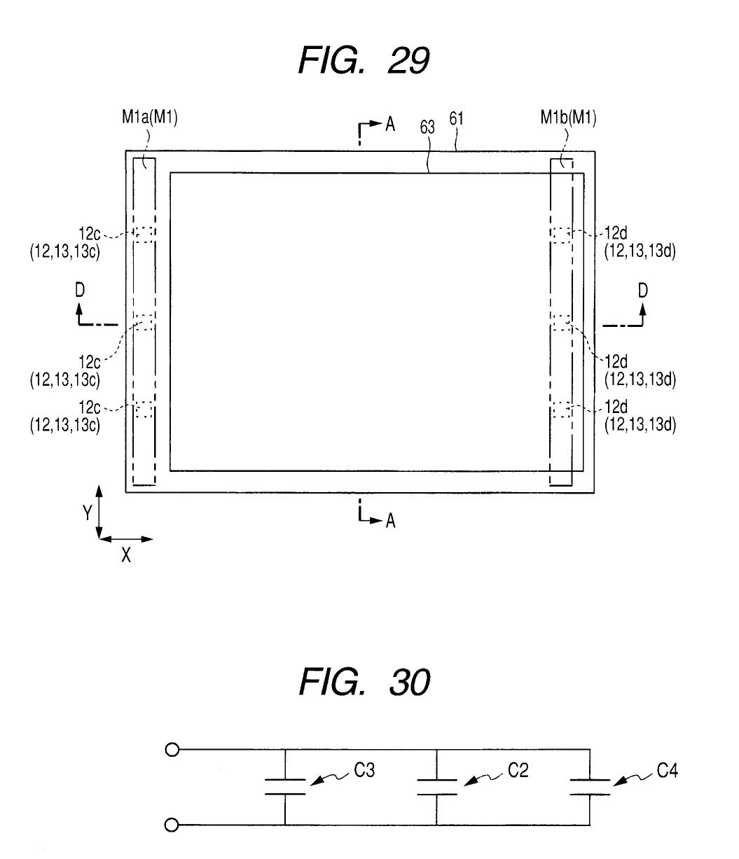

FIG. 26 is a principal part circuit diagram of the semiconductor device of this embodiment, FIG. 27 and FIG. 28 are the principal part cross-sectional views of the semiconductor device of this embodiment, and FIG. 29 is a principal part plan view of the semiconductor device of this embodiment.

FIG. 26 corresponds to the FIG. 1 of above-mentioned Embodiment 1, and the circuit (equivalent circuit) formed in the capacitor formation region of a semiconductor device shown in FIG. 27-FIG. 29 is shown. As for FIG. 27 and FIG. 28, the cross-sectional view of the capacitor formation region of a semiconductor device is shown, and FIG. 27 corresponds to the FIG. 2 of above-mentioned Embodiment 1. The same plane position (capacitor formation region) as the FIG. 5-FIG. 10 of above-mentioned Embodiment 1 is shown in FIG. 29. The plane layout of lower electrode 61 and upper electrode 63 of capacitive element C4, and wiring M1 is shown in FIG. 29. The section of the A-A line of FIG. 29 corresponds to FIG. 27, and the section of a D-D line corresponds to FIG. 28. Therefore, the section corresponding to the FIG. 19 of above-mentioned Embodiment 3 is shown in FIG. 28. Also in this embodiment, since the plane layout of wirings M2-M6 is the same as that of the FIG. 6-FIG. 10 of above-mentioned Embodiment 1, the illustration is omitted here.

Since wiring M1 and insulation film 14, and the upper structure rather than them are the same as that of the semiconductor device of above-mentioned Embodiment 1 about the semiconductor device of this embodiment, the explanation is omitted and the structure below wiring M1 (and insulation film 14) is explained here.

In the semiconductor device of this embodiment, as shown in FIG. 27-FIG. 28, element isolation region 2 is formed in semiconductor substrate 1 in the whole capacitor formation region. On element isolation region 2 of a capacitor formation region, lower electrode (a lower electrode film, a conductor film, a conductor film pattern) 61 is formed. Lower electrode 61 consists of a silicon film (patterned silicon film) like a polycrystalline silicon film (doped polysilicon film) desirably. Impurities are introduced and the polycrystalline silicon film which forms lower electrode 61 is low resistivity. Lower electrode 61 can be formed by, for example forming the polycrystalline silicon film (doped polysilicon film) of low resistivity with which the impurity was introduced on the whole main surface of semiconductor substrate 1, and patterning this polycrystalline silicon film using the photolithography method and the dry etching method.

On lower electrode 61, upper electrode 63 is formed via insulation film 62. Insulating film 62 consists of a silicon oxide film or a silicon nitride film, for example. Upper electrode 63 consists of a silicon film (patterned silicon film) like a polycrystalline silicon film (doped polysilicon film) desirably. Impurities are introduced and the polycrystalline silicon film which forms upper electrode 63 is low resistivity. Insulating film 62, and upper electrode 63 on insulation film 62 can be formed on lower electrode 61 by forming the laminated film of the insulation film for insulation film 62 and the polycrystalline silicon film for upper electrode 63 (doped polysilicon film) so that lower electrode 61 may be covered on the main surface of semiconductor substrate 1 and patterning this laminated film, for example.

With lower electrode 61, insulation film 62, and upper electrode 63, capacitive element (PIP type capacitive element) C4 is formed. Lower electrode 61 functions as one electrode of capacitive element C4, upper electrode 63 functions as the other electrode of capacitive element C4, and insulation film 62 functions as a capacitance insulation film (dielectric film) of capacitive element C4. Upper electrode 63 is not formed on the whole surface of lower electrode 61. At least a part of lower electrodes 61 is in the state where it is not covered with upper electrode 63.

Capacitive element C4 is the so-called PIP (Polysilicon Insulator Polysilicon) type capacitive element. A PIP type capacitive element is a capacitive element (polysilicon capacitive element) which consists of a polysilicon layer (here lower electrode 61 and upper electrode 63) of two layers, and an insulation film (here insulation film 62) inserted between them here. Therefore, a PIP type capacitive element can be regarded as the capacitive element which uses as a lower electrode the first polycrystalline silicon layer (here lower electrode 61) formed on semiconductor substrate 1 and uses as an upper electrode the second polycrystalline silicon layer (here upper electrode 63) formed via the insulation film (here insulation film 62) on the first polycrystalline silicon layer (lower electrode 61).

A side wall insulation film (not shown) can be formed on the side wall of lower electrode 61 and upper electrode 63 according to need. A metal silicide layer (not shown) can also be formed in the upper part of (the polycrystalline silicon films which form) lower electrode 61 and upper electrode 63 according to a salicide process etc. When forming the metal silicide layer, the contact resistance between lower electrode 61 and upper electrode 63, and plug 13 formed later etc. can be reduced.

On semiconductor substrate 1, insulation film (interlayer insulation film) 11 is formed so that the layered product of lower electrode 61, insulation film 62, and upper electrode 63 may be covered. Contact hole 12 is formed in insulation film 11, and plug 13 is formed and embedded in contact hole 12.

In this embodiment, contact hole 12, and plug 13 which fills it are formed in the upper part of upper electrode 63, and the upper part of the portion of the lower electrodes 61 which is not covered with upper electrode 63 in the capacitor formation region.

Contact hole 12c of the contact holes 12 is formed in the upper part of the portion of the lower electrodes 61 which is not covered with upper electrode 63, and lower electrode 61 is exposed at the bottom. Contact hole 12d of the contact holes 12 is formed in the upper part of upper electrode 63, and upper electrode 63 is exposed at the bottom. Therefore, as for plug 13c embedded in contact hole 12c among plugs 13, the bottom is electrically connected in contact with lower electrode 61. As for plug 13d embedded in contact hole 12d among plugs 13, the bottom is electrically connected in contact with upper electrode 63.

On insulation film 11 where plug 13 was embedded, the same structure as above-mentioned Embodiment 1 is formed. That is, wirings M1-M6, insulation films 14, 17, 18, 21, 22, 25, 26, 29, 30, and 33, through holes 15, 19, 23, 27, and 31, and plugs 16, 20, 24, 28, and 32 are formed like above-mentioned Embodiment 1.

The structure above the upper surface of insulation film 11 of the semiconductor device of this embodiment (wirings M1-M6 are included) is the same as that of the semiconductor device of above-mentioned Embodiment 1 almost. For this reason, also in this embodiment, the pattern of (wiring part M1a, M1b, and metallic pattern MP1, MP2, MP3, MP4 of) wirings M1-M6 in a capacitor formation region is the same as that of above-mentioned Embodiment 1 (above-mentioned FIG. 5-FIG. 10). Therefore, also in this embodiment, wiring part M1a of wiring M1, and wiring part MC1 and MC3 of wirings M2-M6 are formed in the position (preferably in the same position) which extends and exists to the Y direction, and overlaps in plan view like above-mentioned Embodiment 1. Wiring part M1b of wiring M1, and wiring part MC2 and MC4 of wirings M2-M6 are formed in the position (preferably in the same position) which extends and exists to the Y direction, and overlaps in plan view.

And in this embodiment, as shown in FIG. 27-FIG. 29, contact hole 12c, and plug 13c which fills it are arranged in the position which overlaps with lower electrode 61, and wiring part M1a of wiring M1 in plan view. Lower electrode 61 of capacitive element C4 is electrically connected to wiring part M1a of wiring M1 via this plug 13c. Contact hole 12d, and plug 13d which fills it are arranged in the position which overlaps with upper electrode 63, and wiring part M1b of wiring M1 in plan view. Upper electrode 63 of capacitive element C4 is electrically connected to wiring part M1b of wiring M1 via this plug 13d. Since upper electrode 63 extends and exists also directly under wiring part M1b of wiring M1, between wiring part M1b of wiring M1 and upper electrodes 63 is connectable with plug 13d. Since wiring part M1a of wiring M1 extends and exists also right above the region of the lower electrodes 61 which is not covered with upper electrode 63, it can connect between lower electrode 61, and wiring part M1a of wiring M1 with plug 13c.

Therefore, in this embodiment, the first electrode (first electrode which consists of metallic pattern MP1 and MP3 of wirings M2-M6) of capacitive element C2 electrically connects with wiring part M1a of wiring M1 via plug 16, and electrically connects with lower electrode 61 of capacitive element C4 via plug 13c further. The second electrode (second electrode which consists of metallic pattern MP2 and MP4 of wirings M2-M6) of capacitive element C2 electrically connects with wiring part M1b of wiring M1 via plug 16, and electrically connects with upper electrode 63 of capacitive element C4 via plug 13d further. For this reason, as shown also in FIG. 26, capacitive element C2 and capacitive element C4 are connected in parallel. The circuit which connected capacitive element C2 and C4 in parallel electrically connects with the element formed in other regions in a semiconductor device, or the bonding pad according to need with wiring (not shown) of one layer or two or more layers of wirings M1-M6 and the upper wiring layers rather than them etc.

Thus, in this embodiment, a plurality of capacitive elements C4 and C2 from which a kind differs mutually are accumulated and arranged on semiconductor substrate 1, and they are connected in parallel. Therefore, capacitive elements C4 and C2 are arranged at a different layer of the same plane region. Although a kind differs between capacitive element C4 and capacitive element C2 mutually, they are a capacitive element from which characteristics (C-V characteristics, i.e., voltage dependency of capacitance) also differ. For this reason, in this embodiment, a plurality of capacitive elements C4 and C2 from which characteristics differ mutually are accumulated and arranged on semiconductor substrate 1, and they are connected in parallel.

Also in this embodiment, the almost same effect as above-mentioned Embodiment 1 can be acquired. However, in capacitive element C1 and capacitive element C4, when a plane size is the same, capacitive element C1 of the MOS type capacitive element which is easy to make a capacitance insulation film thin can enlarge a capacitance value more. For this reason, in order to enlarge the capacitance value per area of a capacitor formation region, above-mentioned Embodiment 1 using capacitive element C1 is more advantageous. When it gives priority to the area reduction of a semiconductor device, it is preferred to use above-mentioned Embodiment 1. On the other hand, in capacitive element C1 and capacitive element C4, an electrical property (C-V characteristics) of capacitive element C4 is better (C-V characteristics of capacitive element C4 is closer to a flat, and the voltage dependency of a capacitance value is smaller than capacitive element C1). For this reason, when it gives priority to an electrical property, this embodiment which used capacitive element C4 is more advantageous. At this embodiment, a large capacity capacitive element is formed in a small plane region by accumulating a plurality of capacitive elements C4 and C2, and connecting them in parallel. It becomes difficult for a capacitance value to depend on a bias voltage value by using capacitive element C4 which is a PIP type capacitive element which is easy to make voltage dependency of a capacitance value small compared with an MOS type capacitive element. Therefore, the characteristics of a circuit using a capacitive element can be improved more. Therefore, the capacitive element (capacitive element which consists of capacitive elements C4 and C2 by which parallel connection was done) which is large capacity in total and has flat C-V characteristics (C-V characteristics that voltage dependency is small) is realizable.

Also in this embodiment, a plurality of capacitive elements C4 and C2 are connected using a plurality of wiring parts (wiring part M1a of wiring M1, and wiring part MC1 and MC3 of wirings M2-M6, and wiring part M1b of wiring M1, and wiring part MC2 and MC4 of wirings M2-M6) which are formed on the semiconductor substrate and arranged in a mutually different layer in the position which overlaps in plan view. Concretely, wiring part M1a of wiring M1, wiring part MC1 of wiring M2, wiring part MC3 of wiring M3, wiring part MC1 of wiring M4, wiring part MC3 of wiring M5, and wiring part MC1 of wiring M6 which were formed in a layer which is mutually different are arranged in the position (preferably in the same position) which overlaps in plan view. One electrodes of capacitive elements C4 and C2 are electrically connected using these. Further, wiring part M1b of wiring M1, wiring part MC2 of wiring M2, wiring part MC4 of wiring M3, wiring part MC2 of wiring M4, wiring part MC4 of wiring M5, and wiring part MC2 of wiring M6 which were formed in a mutually different layer are arranged in the position (preferably in the same position) which overlaps in plan view. The other electrodes of capacitive elements C4 and C2 are electrically connected using these. Hereby, a plurality of capacitive elements C4 and C2 are connected in parallel. By doing in this way, parallel connection of a plurality of capacitive elements C4 and C2 can be done efficiently, and wire routing for connecting in parallel can be shortened more. A parasitic resistance component can be made smaller and the characteristics of the circuit which connected in parallel and formed capacitive elements C4 and C2 can be improved more.

### Embodiment 6

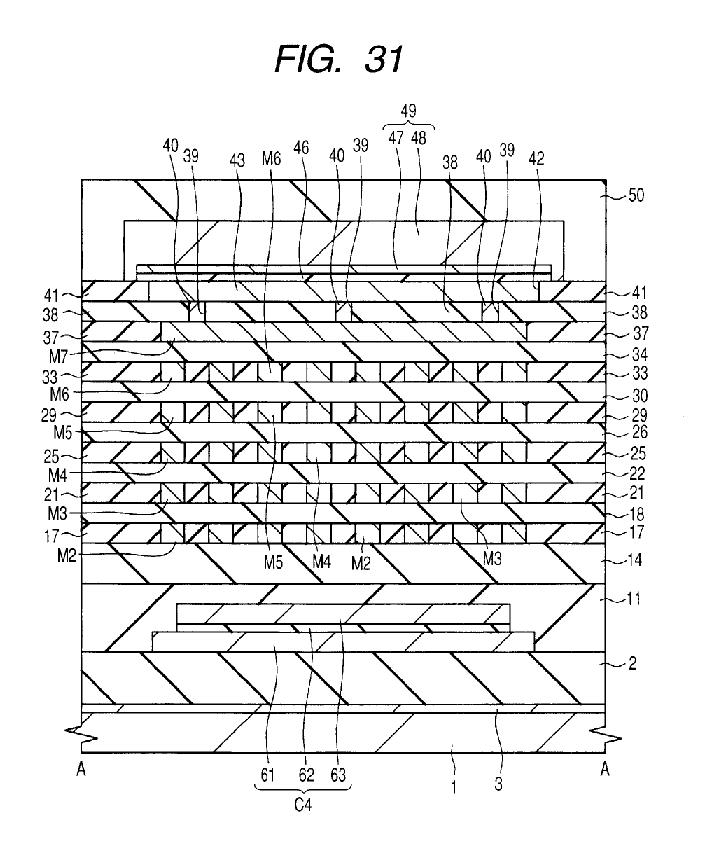

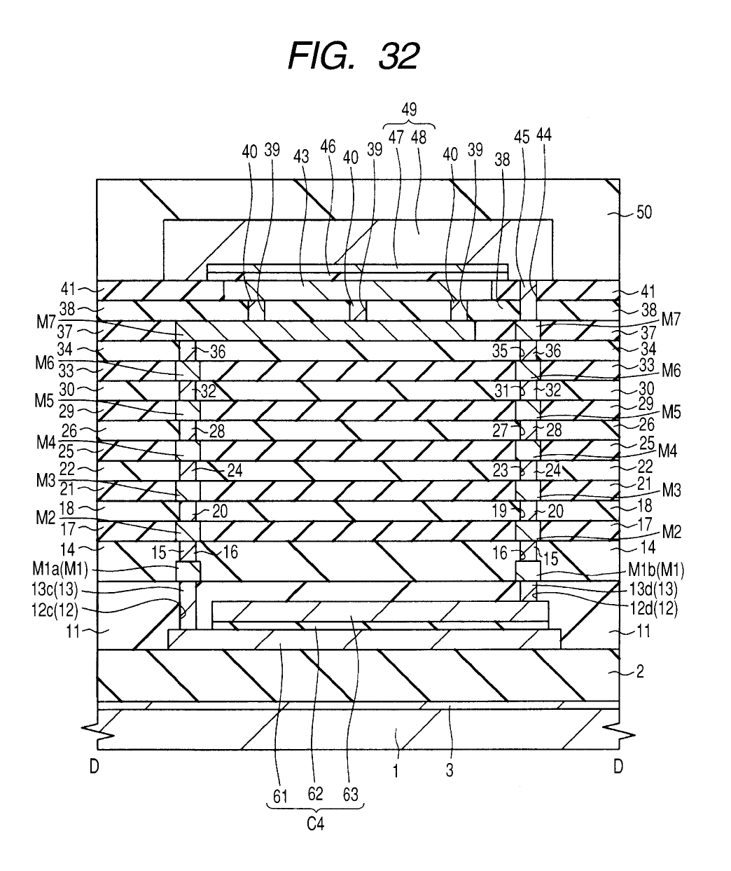

FIG. 30 is a principal part circuit diagram of the semiconductor device of this embodiment, and corresponds to the FIG. 17 of above-mentioned Embodiment 3. FIG. 31 and FIG. 32 are the principal part cross-sectional views of the semiconductor device which is this embodiment, and correspond to the FIG. 18 and FIG. 19 of above-mentioned Embodiment 3, respectively.

In above-mentioned Embodiment 3, capacitive elements C1, C2, and C3 were formed in the capacitor formation region. This embodiment corresponds to what formed the same PIP type capacitive element C4 as above-mentioned Embodiment 5 instead of capacitive element C1 to it.

Namely, as shown in FIG. 31 and FIG. 32, as for the semiconductor device of this embodiment, insulation film 33 and wiring M6, and the structure below them are the same as that of the semiconductor device of above-mentioned Embodiment 5, and the structure above insulation film 33 and wiring M6 of above-mentioned Embodiment 3 is formed (arranged) on insulation film 33 and wiring M6.

In this embodiment, like above-mentioned Embodiment 5, the first electrode (first electrode which consists of metallic patterns MP1 and MP3 of wirings M2-M6) of capacitive element C2 electrically connects with lower electrode 61 of capacitive element C4 via plug 16, wiring part M1a of wiring M1, and plug 13c. In this embodiment, like above-mentioned Embodiment 5, the second electrode (second electrode which consists of metallic patterns MP2 and MP4 of wirings M2-M6) of capacitive element C2 electrically connects with upper electrode 63 of capacitive element C4 via plug 16, wiring part M1b of wiring M1, and plug 13d. Further, in this embodiment, lower electrode 43 of capacitive element C3 is electrically connected to the first electrode (first electrode which consists of metallic pattern MP1 and MP3 of wirings M2-M6) of capacitive element C2 like above Embodiment 3 and 4. In this embodiment, upper electrode 49 of capacitive element C3 is electrically connected with the second electrode (second electrode which consists of metallic pattern MP2 and MP4 of wirings M2-M6) of capacitive element C2 like above Embodiment 3 and 4.

Therefore, in this embodiment, lower electrode 43 of capacitive element C3, the first electrode (first electrode which consists of metallic pattern MP1 and MP3 of wirings M2-M6) of capacitive element C2, and lower electrode 61 of capacitive element C4 are electrically connected mutually. And upper electrode 49 of capacitive element C3, the second electrode (second electrode which consists of metallic pattern MP2 and MP4 of wirings M2-M6) of capacitive element C2, and upper electrode 63 of capacitive element C4 are electrically connected mutually. For this reason, as shown also in FIG. 30, capacitive element C4, capacitive element C2, and capacitive element C3 are connected in parallel. The circuit which connected capacitive element C2, C3, and C4 in parallel is electrically connected with an element or a bonding pad formed in other regions in a semiconductor device according to need by the wiring (not shown) of one layer or two or more layers among wirings M1-M7 etc.

Thus, in this embodiment, a plurality of capacitive elements C4, C2, and C3 from which a kind differs mutually are accumulated and arranged on semiconductor substrate 1, and they are connected in parallel. Therefore, capacitive elements C4, C2, and C3 are arranged at a different layer of the same plane region. Although a kind differs among capacitive element C4, capacitive element C2, and capacitive element C3 mutually, they are a capacitive element from which characteristics (C-V characteristics, i.e., voltage dependency of capacitance) also differ. For this reason, in this embodiment, a plurality of capacitive elements C4, C2, and C3 from which characteristics differ mutually are accumulated and arranged on semiconductor substrate 1, and they are connected in parallel.

In this embodiment, in addition to capacitive elements C4 and C2, capacitive element C3 has been further arranged on capacitive element C4 and C2, and these capacitive elements C4, C2, and C3 are connected in parallel. Therefore, in addition to the effect acquired by above-mentioned Embodiment 5, the capacitive element (capacitive element which consists of capacitive elements C2, C3, and C4 by which parallel connection was done) of further large capacity can be formed in a small plane region. For this reason, it becomes very advantageous to the area reduction of a semiconductor device which has a capacitive element. It becomes very advantageous to coexistence of the realization of high-capacity of a capacitive element, and the area reduction of a semiconductor device.

Also in this embodiment, a plurality of capacitive elements C4, C2, and C3 are connected using a plurality of wiring parts (wiring part M1a of wiring M1, wiring part MC1 and MC3 of wirings M2-M6, and wiring part M7a of wiring M7, and wiring part M1b of wiring M1, wiring part MC2 and MC4 of wirings M2-M6, and wiring part M7b of wiring M7) arranged in the position which was formed on the semiconductor substrate, and with which they are mutually different layers and overlap in plan view. Concretely, wiring part M1a of wiring M1, wiring part MC1 of wiring M2, wiring part MC3 of wiring M3, wiring part MC1 of wiring M4, wiring part MC3 of wiring M5, wiring part MC1 of wiring M6, and wiring part M7a of wiring M7 which were formed in layers which are mutually different are arranged in the position (preferably in the same position) which overlaps in plan view. One electrodes of capacitive elements C4, C2, and C3 are electrically connected using these. Further, wiring part M1b of wiring M1, wiring part MC2 of wiring M2, wiring part MC4 of wiring M3, wiring part MC2 of wiring M4, wiring part MC4 of wiring M5, wiring part MC2 of wiring M6, and wiring part M7b of wiring M7 which were formed in mutually different layers are arranged in the position (preferably in the same position) which overlaps in plan view. The other electrodes of capacitive elements C4, C2, and C3 are connected using these. Hereby, a plurality of capacitive elements C4, C2, and C3 are connected in parallel. By doing in this way, parallel connection of a plurality of capacitive elements C4, C2, and C3 can be done efficiently, and wire routing for connecting in parallel can be shortened more. A parasitic resistance component can be made smaller and the characteristics of the circuit which connected in parallel and formed capacitive elements C4, C2, and C3 can be improved more.

### Embodiment 7

In Embodiments 1-6 explained until now, a plurality of capacitive elements from which a kind differs mutually (which correspond to capacitive elements C1 and C2 in above Embodiments 1 and 2, correspond to capacitive elements C1, C2, and C3 in above-mentioned Embodiment 3, correspond to capacitive elements C2 and C3 in above-mentioned Embodiment 4, correspond to capacitive elements C4 and C2 in above-mentioned Embodiment 5, and correspond to capacitive elements C4, C2, and C3 in above-mentioned Embodiment 6) are accumulated and arranged on semiconductor substrate 1, and connected in parallel. Although these capacitive elements C1-C4 are capacitive elements from which a kind differs mutually, they are also capacitive elements from which characteristics (C-V characteristics, i.e., voltage dependency of capacitance) differ mutually.

A plurality of capacitive elements which were accumulated and were connected in parallel include at least two kinds of capacitive elements among the capacitive element of the first kind which consists of an MOS type capacitive element (it corresponds to capacitive element C1), or a PIP type capacitive element (it corresponds to capacitive element C4), the capacitive element of the second kind using the capacitance between the metallic patterns of the same layer (it corresponds to capacitive element C2), and the capacitive elements of the third kind using the capacitance between a lower metal electrode, and the upper metal electrode on the lower metal electrode (it corresponds to capacitive element C3). Those various variations are shown by above Embodiments 1-6. The capacitive elements of the first-the third kind are arranged at a different layer of the same plane region. As shown in above Embodiments 1-6, the first kind of capacitive element (capacitive element C1 or capacitive element C4) is arranged at a lower layer rather than the second kind of capacitive element (capacitive element C2). The third kind of capacitive element (capacitive element C3) is arranged at the upper layer rather than the second kind of capacitive element (capacitive element C2).

Although a plurality of capacitive elements which were accumulated and arranged on semiconductor substrate 1, and were connected in parallel (which correspond to capacitive elements C1 and C2 in above Embodiments 1 and 2, correspond to capacitive elements C1, C2, and C3 in above-mentioned Embodiment 3, correspond to capacitive elements C2 and C3 in above-mentioned Embodiment 4, correspond to capacitive elements C4 and C2 in above-mentioned Embodiment 5, and correspond to capacitive elements C4, C2, and C3 in above-mentioned Embodiment 6) are arranged at a different layer of the same plane region, it is more preferred that a plane size is the same (almost the same). This embodiment explains the desirable design method of the pattern of capacitive elements C1-C4 explained by above Embodiments 1-6.

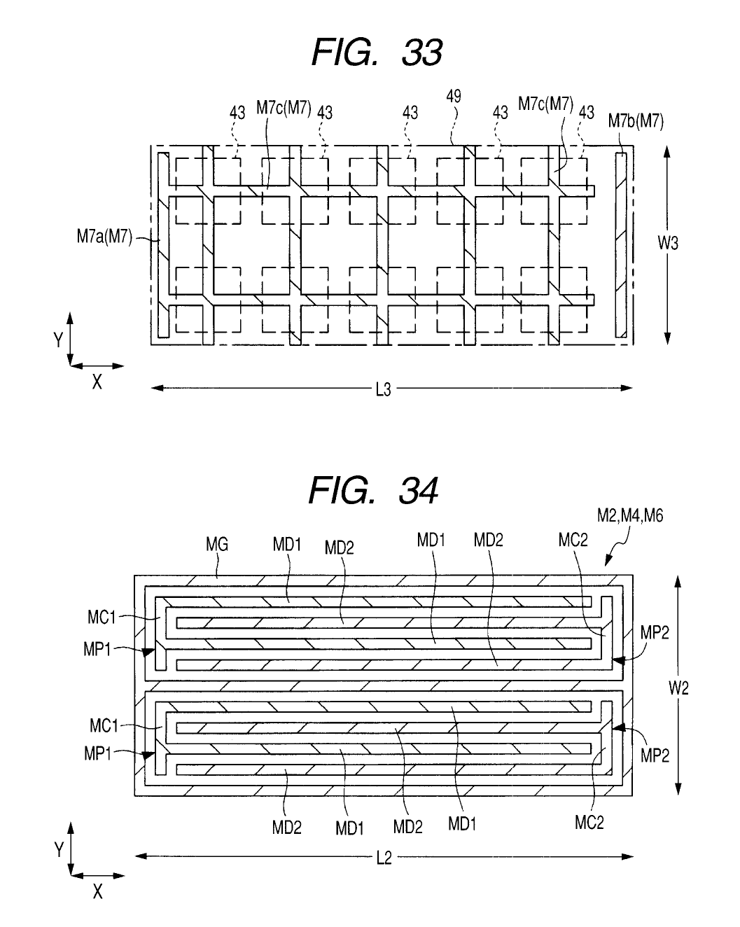

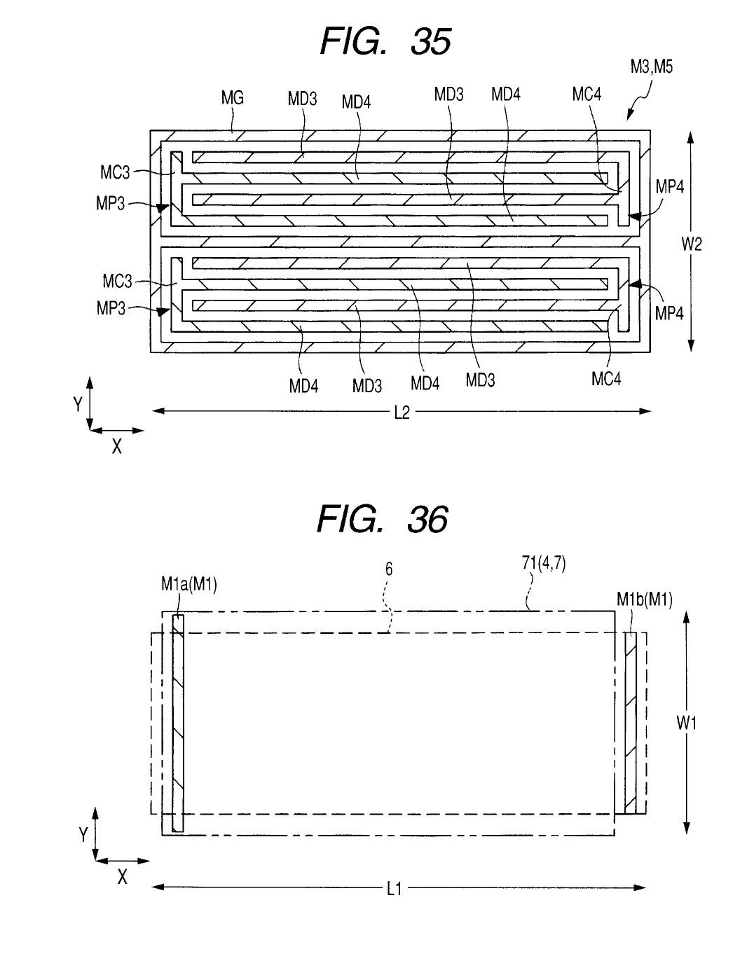

As for FIG. 33-FIG. 36, the plan view of a different layer of the same region (capacitor formation region) is shown. The plane layout of wiring M7, lower electrode 43, and upper electrode 49 in a capacitor formation region is shown in FIG. 33. The plane layout of wirings M2, M4, and M6 is shown in FIG. 34, and the plane layout of wirings M3 and M5 is shown in FIG. 35. The plane layout of upper electrode 6, n-type semiconductor region 71, and wiring M1 is shown in FIG. 36. Although FIG. 33-FIG. 36 are plan views, in order to make a drawing legible, hatching is given to wirings M1-M7. In FIG. 33, a dotted line shows lower electrode 43 and the two-dot chain line has shown upper electrode 49. In FIG. 36, a dotted line shows upper electrode 6 and the two-dot chain line has shown n-type semiconductor region 71. N-type semiconductor region 71 shown in FIG. 36 combines above-mentioned n-type semiconductor region 4 and above-mentioned n-type semiconductor region 7. The portion located under upper electrode 6 corresponds to the above-mentioned n-type semiconductor region 4, and the portion with which upper electrode 6 has not overlapped corresponds to the above-mentioned n-type semiconductor region 7 among n-type semiconductor regions 71.

As above-mentioned Embodiment 3 explained, lower electrode 43 of capacitive element C3 can be formed using damascene technology. However, when the plane size of lower electrode 43 becomes large too much, the problem of dishing may occur in the CMP process at the time of lower electrode 43 formation. For this reason, when enlarging area of the capacitor formation region which forms capacitive element C3 and enlarging the capacitance value of capacitive element C3, as shown in FIG. 33, it is more preferred that lower electrode 43 is divided into plurality (when putting in another way, that a plurality of lower electrodes 43 will be formed). Hereby, it can be prevented that dishing occurs at the time of lower electrode 43 formation.

Each lower electrode 43 which is divided and became plurality is electrically connected with wiring part M7c of wiring M7 extending and existing under each lower electrode 43 via the above-mentioned plug 40, as above-mentioned Embodiment 3 explained. In this embodiment, as shown in FIG. 33, wiring part M7c extending and existing under each lower electrode 43 is formed in one with wiring part M7a of wiring M7, and is electrically connected. For this reason, a plurality of lower electrodes 43 are electrically connected mutually via the above-mentioned plug 40 and wiring part M7c, and are electrically further connected to wiring part M7a.

Since upper electrode 49 can be formed by patterning and it does not generate the problem of dishing, it can be used as the pattern of an one large area. For this reason, as shown in FIG. 33, upper electrode 49 is formed so that a plurality of lower electrode 43 whole may be covered. Although not illustrated in FIG. 33, a capacitance insulation film (the above-mentioned insulation film 46) also covers a plurality of lower electrode 43 whole, and is formed under upper electrode 49. Thus, capacitive element C3 is formed with a plurality of lower electrodes 43, and upper electrode 49 formed via the capacitance insulation film (the above-mentioned insulation film 46) on a plurality of lower electrodes 43.

In FIG. 33, the case where capacitive element C3 is formed with a total of ten lower electrodes 43 of two rows in the Y direction, and 5 columns in the X direction about lower electrode 43, and one upper electrode 49 is illustrated. However, it is not limited to this but the number of lower electrodes 43 can be changed according to need. As above-mentioned Embodiment 3 explained, also when a plurality of lower electrodes 43 are formed like FIG. 33, a plurality of lower electrodes 43 of capacitive element C3, and the first electrode (the first electrode which consists of metallic pattern MP1 and MP3 of wirings M2-M6) of capacitive element C2 are electrically connected via wiring part MC1 and MC3 of wirings M2-M6, and wiring part M7a of wiring M7 which were formed in the position (preferably in the same position) which overlaps in plan view, and the plug which connects between them. As above-mentioned Embodiment 3 explained, a plurality of upper electrodes 49 of capacitive element C3, and the second electrode (the second electrode which consists of metallic pattern MP2 and MP4 of wirings M2-M6) of capacitive element C2 are electrically connected via wiring part MC2 and MC4 of wirings M2-M6, and wiring part M7b of wiring M7 which were formed in the position (preferably in the same position) which overlaps in plan view, and the plug which connects between them.

For this reason, as shown in FIG. 33-FIG. 35, it is preferred to adjust the plane size of capacitive element C3 and the plane size of capacitive element C2. Hereby, while being able to enlarge capacitance of capacitive element C2 and C3, the parallel connection of capacitive element C2 and capacitive element C3 becomes easy. Wire routing can be reduced and connection between capacitive element C2 and C3 via wiring parts MC1-MC4 of the above-mentioned wirings M2-M6, and wiring part M7a and M7b of wiring M7 becomes easy. Minimization of a plane region (area occupied to the main surface of semiconductor substrate 1) required to form capacitive element C2 and C3 and maximization of a capacitance value can be aimed at.

For example, when many lower electrodes 43 are arranged to the Y direction like FIG. 33, and size L3 of the X direction of capacitive element C3 becomes long, as it is shown in FIG. 34 and FIG. 35, it is preferred that size L2 of the X direction of capacitive element C2 is lengthened similarly, and both (L2 and L3) are made almost the same. The flexibility of the design to the size of the X direction of metallic patterns MP1-MP4 of wirings M2-M6 is high. Therefore, according to size L3 of the X direction of capacitive element C3 decided by the size of lower electrode 43 of the X direction, and the number of arrangement of lower electrode 43, the size of the X direction of metallic patterns MP1-MP2 of wirings M2-M6 (the length of the X direction of wiring parts MD1-MD4) is designed. By it, size L3 of the X direction of capacitive element C3 and size L2 of the X direction of capacitive element C2 can be made almost the same.

Similarly, as shown in FIG. 33-FIG. 35, it is preferred to make size W2 of the Y direction of capacitive element C2 and size W3 of the Y direction of capacitive element C3 almost the same. However, the pitch of the Y direction of wiring part MD1 and MD2 of wiring M2, M4, and M6 and the pitch of the Y direction of wiring part MD3 and MD4 of wiring M3 and M5 are prescribed by the photolithography etc., and there is little flexibility of a design change. For this reason, the pitch of the Y direction of wiring parts MD1 and MD2 of wirings M2, M4, and M6 (namely, pitch of the Y direction of wiring parts MD3 and MD4 of wirings M3 and M5), and the number of wiring parts MD1 and MD2 of wirings M2, M4, and M6 (namely, number of wiring parts MD3 and MD4 of wirings M3 and M5) are designed. By it, size W3 of the Y direction of capacitive element C3 and size W2 of the Y direction of capacitive element C2 can be made almost the same.

Hereby, while securing the ease of a layout, a dead space is lost and higher-density (that is, the capacitance value per unit plane region is large) capacitive elements C2, C3 can be formed.

Not only in when a plurality of lower electrodes 43 which form capacitive element C3 are formed like the above-mentioned FIG. 33, but also in when lower electrode 43 which forms capacitive element C3 is set to one like the above-mentioned FIG. 21 of above-mentioned Embodiment 3, it is preferred to adjust the plane size of capacitive element C3 (size of the X direction and the Y direction of capacitive element C3 corresponding to L3 and W3), and the plane size (size of the X direction and the Y direction of capacitive element C2 corresponding to L2 and W2) of capacitive element C2.

When forming capacitive element C1, it is preferred to adjust the plane size of capacitive element C2 and the plane size of capacitive element C1. Hereby, the parallel connection of capacitive element C2 and capacitive element C1 becomes easy, and wire routing can be reduced. Connection between capacitive element C1 and C2 via wiring parts MC1-MC4 of the above-mentioned wirings M2-M6, and wiring part M1a and M1b of wiring M1 becomes easy. Minimization of a plane region (area occupied to the main surface of semiconductor substrate 1) required to form capacitive element C1 and C2 and maximization of a capacitance value can be aimed at.

Compared with metallic patterns MP1-MP4 of wirings M2-M7, the flexibility of a design of the pattern (pattern of upper electrode 6 or n-type semiconductor region 7) of capacitive element C1 is higher. For this reason, when forming capacitive element C1, according to size L2 of the X direction and size W2 of the Y direction of capacitive element C2, the pattern of capacitive element C1 which is an MOS type capacitive element is generated (designed). As shown to FIG. 34-FIG. 36 by it, size L2 of the X direction of capacitive element C2 and size L1 of the X direction of capacitive element C1 can be made almost the same. Size W2 of the Y direction of capacitive element C2 and size W1 of the Y direction of capacitive element C1 can be made almost the same. Hereby, while securing the ease of a layout, a dead space is lost and higher-density (that is, the capacitance value per unit plane region is large) capacitive elements C1 and C2 can be formed.

When forming capacitive elements C1, C2, and C3, it is preferred to adjust the plane size of capacitive element C3, the plane size of capacitive element C2, and the plane size of capacitive element C1. That is, as shown in FIG. 33-FIG. 36, it is preferred to make size L1, L2, and L3 of the X direction of capacitive elements C1, C2, and C3 almost the same, and to make size W1, W2, and W3 of the Y direction of capacitive elements C1, C2, and C3 almost the same. Hereby, the parallel connection of capacitive elements C1, C2, and C3 becomes easy, and wire routing can be reduced. Connection via wiring part M7a and M7b of the above-mentioned wiring M7, wiring parts MC1-MC4 of wirings M2-M6, and wiring part M1a and M1b of wiring M1 between capacitive element C1, C2, and C3 becomes easy. Minimization of a plane region (area occupied to the main surface of semiconductor substrate 1) required to form capacitive element C1, C2, and C3 and maximization of a capacitance value can be aimed at.

When forming capacitive element C4 instead of capacitive element C1 like above Embodiment 5 and 6, it is preferred to adjust the plane size of capacitive element C4 with the plane size of capacitive element C2. That is, it is preferred to make the size of the X direction of capacitive element C4 almost the same as size L2 of the X direction of capacitive element C2, and to make the size of the Y direction of capacitive element C4 almost the same as size W2 of the Y direction of capacitive element C2. Hereby, the parallel connection of capacitive element C4 and capacitive element C2 becomes easy, and wire routing can be reduced. Connection via wiring part M1a and M1b of the above-mentioned wiring M1, and wiring parts MC1-MC4 of wirings M2-M6 between capacitive element C2 and C4 becomes easy. Minimization of a plane region (area occupied to the main surface of semiconductor substrate 1) required to form capacitive element C2 and C4 (or capacitive element C2, C3, C4) and maximization of a capacitance value can be aimed at.

The size (it is equivalent to above L1) of the X direction of capacitive element C1 is equivalent to the size of the X direction of upper electrode 6 in general. The size (it is equivalent to above W1) of the Y direction of capacitive element C1 is equivalent to the size (namely, size of the Y direction of n-type semiconductor region 71) of the Y direction of the region which added n-type semiconductor region 7 to upper electrode 6 in general. The size (it is equivalent to above L2 and W2) of the X direction and the Y direction of capacitive element C2 is equivalent to the size of the X direction and the Y direction of the plane region which metallic pattern MP1, MP2, MP3, and MP4 (or plane region which metallic pattern MP1, MP2, MP3, MP4, and wiring part MG occupy) of wirings M2-M6 occupy in general, respectively. The size (corresponding to above L3 and W3) of the X direction and the Y direction of capacitive element C3 is equivalent to the size of the X direction and the Y direction of upper electrode 49 in general, respectively. The size of the X direction and the Y direction of capacitive element C4 is equivalent to the size of the X direction and the Y direction of lower electrode 61 in general, respectively. As for capacitive elements C1-C4, when the sizes (corresponding to above L1-L3 etc.) of the X direction are in general the same and the sizes (corresponding to above W1-W3 etc.) of the Y direction are in general the same, it can be considered that a plane size is almost the same.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

The present invention is effective in the application to the semiconductor device which has a capacitive element.

What is claimed is:

1. A semiconductor device, comprising:
a semiconductor substrate; and
a plurality of capacitive elements which are accumulated and arranged over the semiconductor substrate and which differ in a kind mutually;
wherein the capacitive elements are connected in parallel.

2. A semiconductor device according to claim 1, wherein
the capacitive elements are arranged at different layers of the same plane region.

3. A semiconductor device according to claim 1, wherein
the capacitive elements include at least two kinds of capacitive elements among a capacitive element of a first kind which has an MOS type capacitive element or a PIP type capacitive element, a capacitive element of a second kind using a capacitance between metallic patterns of the same layer, and a capacitive element of a third kind using a capacitance between a lower metal electrode, and an upper metal electrode over the lower metal electrode.

4. A semiconductor device according to claim 3, wherein
the first kind of capacitive element is arranged rather than the second kind of capacitive element at a lower layer, and the third kind of capacitive element is arranged rather than the second kind of capacitive element at an upper layer.

5. A semiconductor device according to claim 3, wherein
the MOS type capacitive element is a capacitive element which uses a part of the semiconductor substrate as a lower electrode, and uses as an upper electrode a conductor layer formed via a first insulation film over the semiconductor substrate; and
the PIP type capacitive element is a capacitive element which uses as a lower electrode a first polycrystalline silicon layer formed over the semiconductor substrate, and uses as an upper electrode a second polycrystalline silicon layer formed via a second insulation film over the first polycrystalline silicon layer.

6. A semiconductor device according to claim 3, wherein
the third kind of capacitive element is a capacitive element which does not use a capacitance between metallic patterns of the same layer although a capacitance between the lower metal electrode and the upper metal electrode is used.

7. A semiconductor device according to claim 6, wherein
the upper metal electrode of the third kind of capacitive element is formed using a metal layer of the same layer as a metal layer for bonding pad electrodes of the semiconductor device.

8. A semiconductor device according to claim 3, wherein
the second kind of capacitive element is a capacitive element using a capacitance between a first metallic pattern and a second metallic pattern which are formed in the same layer;
the first metallic pattern has a pattern shape with which a plurality of first conductor parts extending and existing in a first direction are connected in a first connection part extending and existing in a second direction which crosses in the first direction; and
the second metallic pattern has a pattern shape with which a plurality of second conductor parts which extend and exist in the first direction, and have been arranged between the first conductor parts, respectively are connected in a second connection part extending and existing in the second direction.

9. A semiconductor device according to claim 3, wherein
the metallic pattern which forms the second kind of capacitive element is formed of a wiring layer formed over the semiconductor substrate.

10. A semiconductor device according to claim 9, comprising:
a plurality of wiring layers formed over the semiconductor substrate;
wherein the metallic pattern which forms the second kind of capacitive element is formed in one or more layers of the wiring layers.

11. A semiconductor device according to claim 9, comprising:
a plurality of wiring layers formed over the semiconductor substrate;
wherein
the metallic pattern which forms the second kind of capacitive element is formed in two or more layers of the wiring layers; and
the second kind of capacitive element is formed using a capacitance between the metallic patterns of the same layer, and a capacitance between the metallic patterns of different layers.

12. A semiconductor device according to claim 1, comprising:
a plurality of wiring parts which are formed over the semiconductor substrate and arranged in mutually different layers and in a position which overlaps in plan view;
wherein the capacitive elements are connected using the wiring parts.

13. A semiconductor device according to claim 1, wherein
the capacitive elements have almost the same plane size.

14. A semiconductor device, comprising:
a semiconductor substrate; and
a plurality of capacitive elements which are accumulated and arranged over the semiconductor substrate and which differ in characteristics mutually;
wherein the capacitive elements are connected in parallel.

15. A semiconductor device according to claim 14, wherein
the capacitive elements are arranged at different layers of the same plane region.

16. A semiconductor device according to claim 14, wherein
the capacitive elements have almost the same plane size.

17. A semiconductor device according to claim 14, wherein
the capacitive elements include at least two kinds of capacitive elements among a capacitive element of a first kind which has an MOS type capacitive element or a PIP type capacitive element, a capacitive element of a second kind using a capacitance between metallic patterns of the same layer, and a capacitive element of a third kind using a capacitance between a lower metal electrode, and an upper metal electrode over the lower metal electrode.

18. A semiconductor device according to claim 17, wherein
the first kind of capacitive element is arranged rather than the second kind of capacitive element at a lower layer, and the third kind of capacitive element is arranged rather than the second kind of capacitive element at an upper layer.

19. A semiconductor device according to claim 17, wherein
the third kind of capacitive element is a capacitive element which does not use a capacitance between metallic patterns of the same layer although a capacitance between the lower metal electrode and the upper metal electrode is used.

20. A semiconductor device according to claim 14, comprising:
a plurality of wiring parts which are formed over the semiconductor substrate and arranged in mutually different layers and in a position which overlaps in plan view;
wherein the capacitive elements are connected using the wiring parts.
